(19) United States
(12) Patent Application Publication
(10) Pub. No.: US 2025/0236738 A1
(43) Pub. Date: Jul. 24, 2025

(54) RESIN COMPOSITION, ARTICLE MADE THEREFROM AND USE THEREOF

(71) Applicant: Elite Electronic Material (KunShan) Co., Ltd., Kunshan City (CN)

(72) Inventors: Zheng JIA, Kunshan City (CN); Rongtao WANG, Kunshan City (CN); Yan ZHANG, Kunshan City (CN); Xueyan JIANG, Kunshan City (CN)

(21) Appl. No.: 18/623,463

(22) Filed: Apr. 1, 2024

(30) Foreign Application Priority Data
Jan. 19, 2024 (CN) 2024100842395

(51) Int. Cl. C09D 4/06; C09D 7/65; C09D 115/00; H05K 3/00

(52) U.S. Cl. CPC C09D 4/06; C09D 7/65; C09D 115/00; H05K 3/0094

(57) ABSTRACT

A resin composition, an article made therefrom and a use thereof are provided. The resin composition includes: 100 parts by weight of a maleic anhydride-modified polyolefin; 5 to 40 parts by weight of a maleimide resin; and 30 to 90 parts by weight of an acrylate monomer, its oligomer or a combination thereof, the acrylate monomer having two or more unsaturated C═C double bonds. The resin composition may be used to fabricate different articles and may be used in a printed circuit board hole-plugging process or a printed circuit board circuit filling process. The resin composition or the article made therefrom may achieve improvements in one or more properties including varnish shelf life, percent of organic volatile matters, dissipation factor, glass transition temperature, percent of thermal expansion in Z-axis, copper foil peeling strength, water absorption ratio and percent of cure shrinkage.

### CROSS-REFERENCE TO RELATED APPLICATION

This application claims the priority benefits of China Patent Application No. 2024100842395, filed on Jan. 19, 2024. The entirety of the above-mentioned patent application is hereby incorporated by reference herein and made a part of this specification.

### BACKGROUND

### 1. Field of the Disclosure

The present disclosure relates to a resin composition, an article made therefrom and a use thereof, more particularly to a resin composition useful in a printed circuit board (PCB) hole-plugging process or a printed circuit board circuit filling process.

### 2. Description of Related Art

With the development of miniaturization of assembly components, PCB is becoming increasingly smaller and thinner. The resin hole-plugging process is a new technology invented to reduce the PCB design size to accommodate the assembly components, which effectively improves the reliability and manufacturing process capability of products with blind/buried holes structure, high density interconnect (HDI) structure and thick copper structure. At the same time, the use of resin hole-plugging process also solves problems that cannot be solved by using green oil hole-plugging process or lamination filling. For example, by using resin to fill the blind/buried holes structure in the inner layer or using resin to fill the open areas of thick copper circuits and then laminating, the contradiction between the thickness control of the dielectric layer of lamination and the design of inner layer resin filling can be balanced. For example, using resin to fill through holes improves the reliability problems caused by green oil hole-plugging process. However, in prior arts, the resin composition used in the hole-plugging process is mainly prepared from conventional epoxy resin in conjunction with calcium carbonate, which has problems of poor properties, such as one or more poor properties including high water absorption ratio and dissipation factor, short varnish shelf life, high percent of organic volatile matters, high percent of thermal expansion in Z-axis, high percent of cure shrinkage, low glass transition temperature, and low copper foil peeling strength. Therefore, it cannot meet the requirements of printed circuit boards for signal transmission at high frequency and high speed.

### SUMMARY

To overcome the problems facing prior arts, particularly one or more of the above-mentioned technical problems of conventional materials, it is a primary object of the present disclosure to provide a resin composition, an article made therefrom and a use of the resin composition in a printed circuit board hole-plugging process or a printed circuit board circuit filling process which may overcome at least one of the above-mentioned technical problems.

To achieve the above-mentioned objects, the present disclosure provides a resin composition, comprising: 100 parts by weight of a maleic anhydride-modified polyolefin; 5 to 40 parts by weight of a maleimide resin; and 30 to 90 parts by weight of an acrylate monomer, its oligomer or a combination thereof, the acrylate monomer having two or more unsaturated C═C double bonds.

For example, in one embodiment, the maleic anhydride-modified polyolefin comprises maleic anhydride-adducted polybutadiene, maleic anhydride-adducted polyisoprene, maleic anhydride-adducted styrene-butadiene copolymer, maleic anhydride-adducted styrene-isoprene copolymer, maleic anhydride-styrene copolymer or a combination thereof.

For example, in one embodiment, the maleimide resin comprises 4,4′-diphenylmethane bismaleimide, polyphenylmethane maleimide, bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-dimethylphenyl maleimide, N-2,6-dimethylphenyl maleimide, N-phenylmaleimide, vinyl benzyl maleimide, maleimide containing indane structure, maleimide containing isopropyl and m-arylene structures, maleimide containing biphenyl alkylene structure, maleimide containing aliphatic structure with 10 to 50 carbon atoms, or a combination thereof.

For example, in one embodiment, the maleimide resin has a maleimide group and an aromatic group bonded with the maleimide group.

For example, in one embodiment, the acrylate monomer comprises tricyclodecane dimethanol di(meth)acrylate, dioxane glycol di(meth)acrylate, dipropylene glycol di(meth)acrylate, tris(2-hydroxyethyl)isocyanurate tri(meth)acrylate, pentaerythritol tri(meth)acrylate, pentaerythritol tetra(meth)acrylate, di-trimethylolpropane tetra(meth)acrylate, dipentaerythritol penta(meth)acrylate, dipentaerythritol hexa(meth)acrylate or a combination thereof.

For example, in one embodiment, the acrylate monomer has two acrylate groups or three acrylate groups.

For example, in one embodiment, the acrylate monomer or its oligomer has a glass transition temperature of greater than or equal to 90° C. after curing.

For example, in one embodiment, the acrylate monomer or its oligomer has a glass transition temperature of greater than or equal to 150° C. after curing.

For example, in one embodiment, the resin composition does not comprise an organic solvent.

For example, in one embodiment, the resin composition further comprises 1 to 10 parts by weight of an organic silicone oil.

For example, in one embodiment, the organic silicone oil contains an unsaturated C═C double bond.

For example, in one embodiment, the resin composition further comprises a polyolefin different from the maleic anhydride-modified polyolefin, an unsaturated C═C double bond-containing polyphenylene ether resin, a benzoxazine resin, an epoxy resin, an active ester, a phenol resin, an amine curing agent, a polyamide, a polyimide, a cyanate ester resin or a combination thereof.

For example, in one embodiment, the resin composition further comprises an inorganic filler, a flame retardant, a curing accelerator, a polymerization inhibitor, a coloring agent, a surfactant, a toughening agent or a combination thereof.

For example, in one embodiment, the resin composition has a varnish shelf life of greater than 90 days.

For example, in one embodiment, the resin composition has a percent of organic volatile matters as measured by reference to IPC-TM-650 2.4.24.6 of less than or equal to 0.5%.

In another aspect, the present disclosure also provides an article made from the resin composition described above, which comprises a prepreg, a resin film, a laminate or a printed circuit board.

In still another aspect, the present disclosure further provides an article made from the resin composition described above, which comprises a cured product obtained by curing the resin composition (as used hereinafter, the term “cured product” refers a product obtained by curing the resin composition and may be used interchangeably with “resin cured product” or “cured resin product”, unless otherwise specified).

For example, in one embodiment, the article described above has at least one, more or all of the following properties:
a dissipation factor at 10 GHz as measured by reference to JIS C2565 of less than or equal to 0.0038;
a glass transition temperature as measured by reference to IPC-TM-650 2.4.24.5 of greater than or equal to 160° C.;
a percent of thermal expansion in Z-axis as measured by reference to IPC-TM-650 2.4.24.5 of less than or equal to 1.6%;
a copper foil peeling strength as measured by reference to IPC-TM-650 2.4.8 of greater than or equal to 4.5 lb/in;
a water absorption ratio as measured by reference to IPC-TM-650 2.6.2.1 and IPC-TM-650 2.6.16.1 of less than or equal to 0.60%; and
a percent of cure shrinkage as measured and calculated by reference to GB/T4472-2011 of less than or equal to 6.0%.

In still another aspect, the present disclosure provides a use of the resin composition described above in a printed circuit board hole-plugging process or a printed circuit board circuit filling process.

For example, in one embodiment, in the printed circuit board hole-plugging process, at least one electroplated hole of a printed circuit board is filled with a cured product of the resin composition.

For example, in one embodiment, in the printed circuit board circuit filling process, at least one circuit open area of a printed circuit board is covered with a cured product of the resin composition.

### DESCRIPTION OF THE EMBODIMENTS

To enable those skilled in the art to further appreciate the features and effects of the present disclosure, words and terms contained in the specification and appended claims are described and defined. Unless otherwise defined, all technical and scientific terms used herein have the same meaning as commonly understood by those of ordinary skill in the art to which this disclosure pertains. In the case of conflict, the present document and definitions contained herein will control.

While some theories or mechanisms may be proposed herein, the present disclosure is not bound by any theories or mechanisms described regardless of whether they are right or wrong, as long as the embodiments can be implemented according to the present disclosure.

As used herein, “a,” “an” or any similar expression is employed to describe components and features of the present disclosure. This is done merely for convenience and to give a general sense of the scope of the present disclosure. Accordingly, this description should be read to include one or at least one and the singular also includes the plural unless it is obvious to mean otherwise.

As used herein, the term “encompasses,” “encompassing,” “comprises,” “comprising,” “includes,” “including,” “has,” “having” or any other variant thereof is construed as an open-ended transitional phrase intended to cover a non-exclusive inclusion. For example, a composition comprising a list of elements or an article made therefrom encompasses any one or any type of the listed elements and is not necessarily limited to only those elements listed herein, but may also include other elements not expressly listed or inherent to such composition or article. Further, unless expressly stated to the contrary, the term “or” refers to an inclusive or and not to an exclusive or. For example, a condition “A or B” is satisfied by any one of the following: A is true (or present) and B is false (or not present), A is false (or not present) and B is true (or present), and both A and B are true (or present). In addition, whenever open-ended transitional phrases are used, such as “encompasses,” “encompassing,” “comprises,” “comprising,” “includes,” “including,” “has,” “having” or any other variant thereof, it is understood that close-ended transitional phrases such as “consisting of,” “composed by” and “remainder being” and partially open-ended transitional phrases such as “consisting essentially of,” “primarily consisting of,” “mainly consisting of,” “primarily containing,” “composed essentially of,” “essentially having,” etc. are also disclosed and included.

As used herein, “or a combination thereof” means “or any combination thereof” encompasses any combination of two or more of the listed elements. “Any” means “any one”, vice versa. For example, “a composition or an article made therefrom includes A, B, C or a combination thereof” is construed to encompass the following situations: A is true (or present), and B and C are false (or not present); B is true (or present), and A and C are false (or not present); C is true (or present), and A and B are false (or not present); A and B are true (or present), and C is false (or not present); A and C are true (or present), and B is false (or not present); B and C are true (or present), and A is false (or not present); and A, B and C are all true (or present), and other elements not expressly listed but inherent to such composition or article.

As used herein, the term “and” or any other variant thereof is used to connect parallel sentence components, and there is no distinction between the front and rear components. The meaning of the parallel sentence components does not change in the grammatical sense after the position is exchanged.

In this disclosure, features and conditions such as values, numbers, contents, amounts or concentrations are presented as a numerical range or a percentage range merely for convenience and brevity. Therefore, a numerical range or a percentage range should be interpreted as encompassing and specifically disclosing all possible subranges and individual numerals or values therein, including integers and fractions, particularly all integers therein. For example, a range of “1.0 to 8.0” or “between 1.0 and 8.0” should be understood as explicitly disclosing all subranges such as 1.0 to 8.0, 1.0 to 7.0, 2.0 to 8.0, 2.0 to 6.0, 3.0 to 6.0, 4.0 to 8.0, 3.0 to 8.0 and so on and encompassing the endpoint values, particularly subranges defined by integers, as well as disclosing all individual values in the range such as 1.0, 2.0, 3.0, 4.0, 5.0, 6.0, 7.0 and 8.0. Unless otherwise defined, the aforesaid interpretation rule should be applied throughout the present disclosure regardless of broadness of the scope.

Whenever amount, concentration or other numeral or parameter is expressed as a range, a preferred range or a series of upper and lower limits, it is understood that all ranges defined by any pair of the upper limit or preferred value and the lower limit or preferred value are specifically disclosed, regardless whether these ranges are explicitly described or not. In addition, unless otherwise defined, whenever a range is mentioned, the range should be interpreted as inclusive of the endpoints and every integers and fractions in the range.

Given the intended purposes and advantages of this disclosure are achieved, numerals or figures have the precision of their significant digits. For example, 40.0 should be understood as covering a range of 39.50 to 40.49.

As used herein, a Markush group or a list of items is used to describe examples or embodiments of the present disclosure. A skilled artisan will appreciate that all subgroups of members or items and individual members or items of the Markush group or list can also be used to describe the present disclosure. For example, when X is described as being “selected from a group consisting of X1, X2 and X3,” it is intended to disclose the situations of X is X1 and X is X1 and/or X2 and/or X3. In addition, when a Markush group or a list of items is used to describe examples or embodiments of the present disclosure, a skilled artisan will understand that any subgroup or any combination of the members or items in the Markush group or list may also be used to describe the present disclosure. Therefore, for example, when X is described as being “selected from a group consisting of X1, X2 and X3” and Y is described as being “selected from a group consisting of Y1, Y2 and Y3,” the disclosure includes any combination of X is X1 and/or X2 and/or X3 and Y is Y1 and/or Y2 and/or Y3.

Unless otherwise specified, according to the present disclosure, a compound refers to a chemical substance formed by two or more elements bonded with chemical bonds and may comprise a small molecule compound and a polymer compound, but not limited thereto. Any compound disclosed herein is interpreted to not only include a single chemical substance but also include a class of chemical substances having the same kind of components or having the same property.

Unless otherwise specified, according to the present disclosure, a polymer refers to the product formed by monomer(s) via polymerization and usually comprises multiple aggregates of polymers respectively formed by multiple repeated simple structure units by covalent bonds; the monomer refers to the compound forming the polymer. A polymer may comprise a homopolymer, a copolymer, a prepolymer, etc., but not limited thereto. A homopolymer refers to the polymer formed by the polymerization of one monomer. A copolymer refers to the polymer formed by the polymerization of two or more types of monomers. Copolymers comprise: random copolymers, such as a structure of -AABABBBAAABBA-; alternating copolymers, such as a structure of -ABABABAB-; graft copolymers, such as a structure of -AA(A-BBBB)AA(A-BBBB)AAA-; and block copolymers, such as a structure of -AAAAA-BBBBBB-AAAAA-. For example, a styrene-butadiene copolymer disclosed herein is interpreted as comprising a styrene-butadiene random copolymer, a styrene-butadiene alternating copolymer, a styrene-butadiene graft copolymer or a styrene-butadiene block copolymer. A prepolymer refers to a polymer having a lower molecular weight between the molecular weight of monomer and the molecular weight of final polymer, and a prepolymer contains a reactive functional group capable of participating further polymerization to obtain the final polymer product which has been fully crosslinked or cured. The term “polymer” includes but is not limited to an oligomer. An oligomer refers to a polymer with 2 to20, typically 2 to5, repeating units.

To those of ordinary skill in the art to which this disclosure pertains, a resin composition containing an additive and three compounds (e.g., A, B and C), a total of four components, is different from a resin composition containing the additive and a prepolymer formed by the three compounds (e.g., A, B and C), a total of two components, as they are completely different from each other in the aspects of preparation method, physical or chemical properties of the resin composition and properties of an article or product made therefrom. For example, the former involves mixing A, B, C and the additive to form the resin composition; in contrast, the latter involves first subjecting a mixture comprising A, B and C to a prepolymerization reaction at proper conditions to form a prepolymer and then mixing the prepolymer with the additive to form the resin composition. For example, to those of ordinary skill in the art to which this disclosure pertains, the two resin compositions have completely different compositions; in addition, because the prepolymer formed by A, B and C functions completely different from A, B and C individually or collectively in the resin composition, the two resin compositions should be construed as completely different chemical substances and have completely different chemical statuses. For example, to those of ordinary skill in the art to which this disclosure pertains, because the two resin compositions are completely different chemical substances, articles made therefrom will not have the same properties. For example, to a resin composition containing a crosslinking agent and a prepolymer formed by A, B and C, since A, B and C have been partially reacted or converted during the prepolymerization reaction to form the prepolymer, during the process of heating to semi-cure the resin composition at a high temperature condition, a partial crosslinking reaction occurs between the prepolymer and the crosslinking agent but not between A, B and C individually and the crosslinking agent. As such, articles made from the two resin compositions will be completely different and have completely different properties.

Unless otherwise specified, the term “resin” of the present disclosure is a widely used common name of a synthetic polymer and is construed as comprising monomer and its combination, polymer and its combination or a combination of monomer and its polymer, but not limited thereto.

Unless otherwise specified, according to the present disclosure, a modification comprises a product derived from a resin with its reactive functional group modified, a product derived from a prepolymerization reaction of a resin and other resins, a product derived from a crosslinking reaction of a resin and other resins, a product derived from copolymerizing a resin and other resins, etc.

The unsaturated bond described herein, unless otherwise specified, refers to a reactive unsaturated bond, such as but not limited to an unsaturated double bond with the potential of being crosslinked with other functional groups, such as an unsaturated C═C double bond with the potential of being crosslinked with other functional groups, but not limited thereto.

The unsaturated C═C double bond as used herein preferably comprises, but not limited to, a vinyl group, a vinylbenzyl group, a (meth)acryloyloxy group (a.k.a. a (meth)acrylate group), an allyl group or a combination thereof. The term “vinyl group” is construed as comprising a vinyl group and a vinylene group, and the term “(meth)acryloyloxy group” is construed as comprising an acryloyloxy group and a methacryloyloxy group. The term “(meth)acrylate group” is construed as comprising an acrylate group and a methacrylate group.

The term “(meth)acrylate” described herein is construed as comprising acrylate and methacrylate.

Unless otherwise specified, the alkyl group, the alkenyl group and the monomer described herein are construed to encompass various isomers thereof. For example, a propyl group is construed to encompass n-propyl and iso-propyl.

Unless otherwise specified, as used herein, part(s) by weight represents weight part(s) in any weight unit in the resin composition, such as but not limited to kilogram, gram, pound and so on. For example, 100 parts by weight of a maleic anhydride-modified polyolefin may represent 100 kilograms of a maleic anhydride-modified polyolefin or 100 pounds of a maleic anhydride-modified polyolefin, but not limited thereto.

Unless otherwise specified, in the present disclosure, wt % represents weight (or mass) percentage.

It should be understood that all features disclosed herein may be combined in any way to constitute the technical solution of the present disclosure, as long as there is no conflict present in the combination of these features.

Examples and embodiments are described in detail below. It will be understood that these examples and embodiments are exemplary only and are not intended to limit the scope and use of the present disclosure. Unless otherwise specified, processes, reagents and conditions described in the examples are those known in the art.

As described above, the present disclosure provides a resin composition, comprising the following components:
100 parts by weight of a maleic anhydride-modified polyolefin;
5 to 40 parts by weight of a maleimide resin; and
30 to 90 parts by weight of an acrylate monomer, its oligomer or a combination thereof, the acrylate monomer having two or more unsaturated C═C double bonds.

For example, in one embodiment, the maleic anhydride-modified polyolefin refers to a polyolefin modified by maleic anhydride. For example, in one embodiment, the modification methods involved in using maleic anhydride may be various chemical modification methods known in the field to which this disclosure pertains, including but not limited to addition polymerization modification, which includes but is not limited to free radical polymerization, positive ionic (cationic) polymerization, negative ionic (anionic) polymerization or coordination polymerization. For example, in one embodiment, the maleic anhydride monomer undergoes addition polymerization with one or more polyolefins to form the maleic anhydride-modified polyolefin. For example, in one embodiment, the maleic anhydride monomer undergoes addition polymerization with one or more olefin monomers to form a random, alternating, block or graft copolymer, namely maleic anhydride-modified polyolefin.

For example, in one embodiment, the type of polyolefin and olefin monomer suitable for the above modification methods is not particularly limited and may be various polyolefins and olefin monomers known in the field to which this disclosure pertains. In other words, a maleic anhydride may be used to modify various polyolefins and olefin monomers to obtain the maleic anhydride-modified polyolefin of the present disclosure.

For example, in some embodiments, the maleic anhydride-modified polyolefin in the resin composition may be one maleic anhydride-modified polyolefin or a mixture of two or more different maleic anhydride-modified polyolefins.

For example, in one embodiment, the maleic anhydride-modified polyolefin may be any maleic anhydride-modified polyolefins known in the field to which this disclosure pertains, including but not limited to any one of maleic anhydride-adducted polybutadiene, maleic anhydride-adducted polyisoprene, maleic anhydride-adducted styrene-butadiene copolymer, maleic anhydride-adducted styrene-isoprene copolymer, maleic anhydride-styrene copolymer or a combination thereof.

For example, in one embodiment, the anhydride equivalent of the maleic anhydride-modified polyolefin is not particularly limited and may be 100 to 2000 g/eq. For example, in one embodiment, the anhydride equivalent of the maleic anhydride-modified polyolefin may be 100 g/eq., 200 g/eq., 300 g/eq., 400 g/eq., 500 g/eq., 600 g/eq., 700 g/eq., 800 g/eq., 900 g/eq., 1000 g/eq., 1100 g/eq., 1200 g/eq., 1300 g/eq., 1400 g/eq., 1500 g/eq., 1600 g/eq., 1700 g/eq., 1800 g/eq., 1900 g/eq. or 2000 g/eq., but not limited thereto. For example, in one embodiment, preferably, the maleic anhydride-modified polyolefin comprises any one of maleic anhydride-adducted polybutadiene with an anhydride equivalent of 400 to 2000 g/eq., maleic anhydride-adducted styrene-butadiene copolymer with an anhydride equivalent of 1500 to 1700 g/eq. or maleic anhydride-styrene copolymer with an anhydride equivalent of 200 to 1500 g/eq., or a combination thereof.

According to the present disclosure, for example, the maleic anhydride-styrene copolymer may be any maleic anhydride-styrene copolymers known in the field to which this disclosure pertains, wherein the molar ratio of styrene (St) to maleic anhydride (MA) may be 1/1, 2/1, 3/1, 4/1, 6/1, 8/1 or 12/1.

According to the present disclosure, relative to 100 parts by weight of the maleic anhydride-modified polyolefin, the resin composition further comprises 5 to 40 parts by weight of a maleimide resin, such as but not limited to 5 parts by weight, 10 parts by weight, 15 parts by weight, 20 parts by weight, 25 parts by weight, 30 parts by weight, 35 parts by weight or 40 parts by weight of a maleimide resin.

For example, in one embodiment, the maleimide resin may be any maleimide resins known in the field to which this disclosure pertains.

For example, in one embodiment, examples of the maleimide resin include but are not limited to: any one of 4,4′-diphenylmethane bismaleimide, polyphenylmethane maleimide, bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-dimethylphenyl maleimide, N-2,6-dimethylphenyl maleimide, N-phenylmaleimide, vinyl benzyl maleimide (VBM) or a combination thereof.

For example, in another embodiment, examples of the maleimide resin include but are not limited to: any one of maleimide containing indane structure, maleimide containing isopropyl and m-arylene structure, maleimide containing biphenyl alkylene structure, maleimide containing aliphatic structure with 10 to 50 carbon atoms, or a combination thereof.

Unless otherwise specified, the maleimide resin should be construed as including its modification, including but not limited to diallyl compound-modified maleimide resin, diamine-modified maleimide resin, multi-functional amine-modified maleimide resin, acidic phenol compound-modified maleimide resin, cyanate-modified maleimide resin or a combination thereof.

For example, examples of the maleimide resin include but are not limited to products such as BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000, and BMI-7000H available from Daiwakasei Industry, products such as BMI-70 and BMI-80 available from K.I Chemical Industry Co., Ltd., or products such as MIR-3000 and MIR-5000 available from Nippon Kayaku.

For example, the maleimide containing aliphatic structure with 10 to 50 carbon atoms, also known as imide-extended maleimide resin, may include various imide-extended maleimide resins known in the field to which this disclosure pertains. Examples of the maleimide containing aliphatic structure with 10 to 50 carbon atoms suitable for the present disclosure include, but not limited to, products such as BMI-689, BMI-1400, BMI-1500, BMI-1700, BMI-2500, BMI-3000, BMI-5000 and BMI-6000 available from Designer Molecules Inc. The maleimide containing aliphatic structure with 10 to 50 carbon atoms has a maleimide group and an aliphatic group bonded with the maleimide group in its structure.

For example, the maleimide containing indane structure comprises a maleimide of Formula (1), the maleimide containing isopropyl and m-arylene structure comprises a maleimide of Formula (2), and the maleimide containing biphenyl alkylene structure comprises a maleimide of Formula (3).

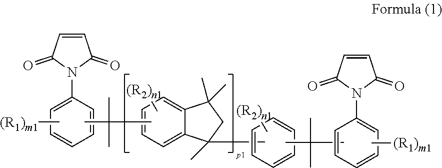

In Formula (1), wherein R1 and R2 are each independently the same or different, and each independently represents a C1 to C10 alkyl group; m1 represents the amount of R1 groups, and m1 is each independently an integer from 0 to 4; n1 represents the amount of R2 groups, and n1 is each independently an integer from 0 to 3; p1 represents the average degree of polymerization, and p1 can be a value from 0.5 to 20.

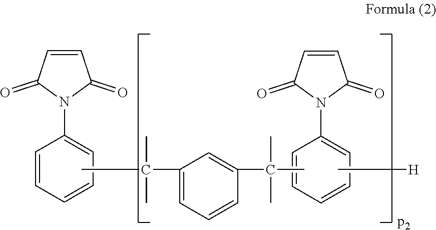

In Formula (2), wherein p2 represents the average degree of polymerization, and p2 can be a value from 1 to 10.

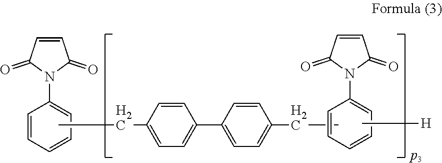

In Formula (3), wherein p3 represents the average degree of polymerization, and p3 can be a value from 1 to 10.

For example, unless otherwise specified, the cyanate-modified maleimide resin (a.k.a. maleimide triazine resin) used herein is not particularly limited and may be any maleimide triazine resins known in the field to which this disclosure pertains. For example, the maleimide triazine resin may be obtained by polymerizing a cyanate ester resin and a maleimide resin. For example, the maleimide triazine resin may be obtained by polymerizing bisphenol A cyanate ester resin and maleimide resin, by polymerizing bisphenol F cyanate ester resin and maleimide resin, by polymerizing phenol novolac cyanate ester resin and maleimide resin or by polymerizing dicyclopentadiene-containing cyanate ester resin and maleimide resin, but not limited thereto. For example, the maleimide triazine resin may be obtained by polymerizing the cyanate ester resin and the maleimide resin at any molar ratio. For example, relative to 1 mole of the maleimide resin, 1 to 10 moles of the cyanate ester resin may be used. For example, relative to 1 mole of the maleimide resin, 1 mole, 2 moles, 4 moles or 6 moles of the cyanate ester resin may be used, but not limited thereto.

For example, in one embodiment, preferably, the maleimide resin has a maleimide group and an aromatic group bonded with the maleimide group in its structure. For example, in one embodiment, the maleimide resin may have a structure including a group of Formula (4):

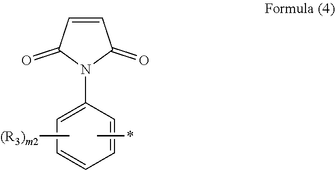

In Formula (4), wherein symbol “*” represents a bonding position between groups; R3 is independently the same or different, and each independently represents a C1 to C10 alkyl group; m2 represents the amount of R3 groups, and m2 can be an integer from 0 to 4.

Among the examples of maleimide resin listed above, except that 1,6-bismaleimide-(2,2,4-trimethyl)hexane and maleimide containing aliphatic structure with 10 to 50 carbon atoms do not contain a group of Formula (4), all the other examples of maleimide resin have the group of Formula (4), that is, they all have a maleimide group and an aromatic group bonded with the maleimide group.

According to the present disclosure, relative to 100 parts by weight of the maleic anhydride-modified polyolefin, the resin composition further comprises 30 to 90 parts by weight of an acrylate monomer, its oligomer or a combination thereof, the acrylate monomer having two or more unsaturated C═C double bonds, such as but not limited to a total of 30 parts by weight, 40 parts by weight, 50 parts by weight, 60 parts by weight, 70 parts by weight, 80 parts by weight or 90 parts by weight of an acrylate monomer, its oligomer or a combination thereof, the acrylate monomer having two or more unsaturated C═C double bonds.

The acrylate monomer (having two or more unsaturated C═C double bonds), its oligomer or a combination thereof can be expressed as an acrylate monomer (having two or more unsaturated C═C double bonds) and/or its oligomer.

According to the present disclosure, the type of acrylate monomer (having two or more unsaturated C═C double bonds) and its oligomer in the resin composition is not particularly limited. For example, the resin composition may comprise any one or more acrylate monomers (having two or more unsaturated C═C double bonds), the resin composition may comprise any one or more oligomers of acrylate monomers (having two or more unsaturated C═C double bonds), or the resin composition may comprise a mixture of any one or more acrylate monomers (having two or more unsaturated C═C double bonds) and any one or more oligomers of acrylate monomers (having two or more unsaturated C═C double bonds).

For example, in one embodiment, the acrylate monomer (having two or more unsaturated C═C double bonds) is preferably a compound having two or more acrylate groups. For example, in one embodiment, preferably, the acrylate monomer (having two or more unsaturated C═C double bonds) is an acrylate monomer having two acrylate groups or three acrylate groups.

Unless otherwise specified, according to the present disclosure, the “acrylate monomer (having two or more unsaturated C═C double bonds)” can also be referred to as “bifunctional or higher acrylate monomer”. For example, the bifunctional or higher acrylate monomer and/or its oligomer may be various bifunctional or higher acrylate monomers and/or oligomers obtained by polymerizing bifunctional or higher acrylate monomers known in the field to which this disclosure pertains. For example, the bifunctional or higher acrylate monomer and/or its oligomer comprises but is not limited to any one of bifunctional acrylate monomer and/or its oligomer, trifunctional acrylate monomer and/or its oligomer, tetrafunctional acrylate monomer and/or its oligomer, pentafunctional acrylate monomer and/or its oligomer, hexafunctional acrylate monomer and/or its oligomer or a combination thereof, and the bifunctional or higher acrylate monomer and its oligomer can be prepared by the Applicant or available from Sartomer.

For example, in one embodiment, the acrylate monomer (having two or more unsaturated C═C double bonds) and its oligomer are in a liquid state at ambient temperature. For example, in one embodiment, the acrylate monomer (having two or more unsaturated C═C double bonds) has a relative molecular mass (Mr) of less than or equal to 2000, and the oligomer obtained by polymerizing the acrylate monomer (having two or more unsaturated C═C double bonds) has a weight average molecular weight (Mw) of less than or equal to 2000.

For example, in one embodiment, the acrylate monomer (having two or more unsaturated C═C double bonds) and/or its oligomer comprises any one of tricyclodecane dimethanol di(meth)acrylate and/or its oligomer, dioxane glycol di(meth)acrylate and/or its oligomer, dipropylene glycol di(meth)acrylate and/or its oligomer, tris(2-hydroxyethyl) isocyanurate tri(meth)acrylate and/or its oligomer, pentaerythritol tri(meth)acrylate and/or its oligomer, pentaerythritol tetra(meth)acrylate and/or its oligomer, di-trimethylolpropane tetra(meth)acrylate and/or its oligomer, dipentaerythritol penta(meth)acrylate and/or its oligomer, dipentaerythritol hexa(meth)acrylate and/or its oligomer, or a combination thereof.

For example, in one embodiment, the acrylate monomer (having two or more unsaturated C═C double bonds) or its oligomer has a glass transition temperature of greater than or equal to 80° C. after being heated to cure completely; that is, the cured product of acrylate monomer (having two or more unsaturated C═C double bonds) or its oligomer has a glass transition temperature of greater than or equal to 80° C. For example, in one embodiment, the acrylate monomer (having two or more unsaturated C═C double bonds) or its oligomer has a glass transition temperature of greater than or equal to 90° C. after being heated to cure completely. Preferably, in one embodiment, the acrylate monomer (having two or more unsaturated C═C double bonds) or its oligomer has a glass transition temperature of greater than or equal to 150° C. after being heated to cure completely.

According to the present disclosure, the acrylate monomer (having two or more unsaturated C═C double bonds) or its oligomer can not only participate in a crosslinking reaction, but also play a role in dissolving and diluting the resin composition. Therefore, for example, in one embodiment, preferably, there is no need to add an additional organic solvent to the resin composition of the present disclosure, and the obtained resin composition has extremely low percent of organic volatile matters, moderate viscosity and stable varnish shelf life.

For example, in one embodiment, preferably, the resin composition does not comprise an organic solvent. For example, in one embodiment, the resin composition does not comprise any one of alcohol, ether, ketone, aromatic hydrocarbon, acetate ester and amide organic solvents or a combination thereof. For example, in one embodiment, the resin composition does not comprise any one of the following organic solvents or a combination thereof: methanol, ethanol, ethylene glycol monomethyl ether, acetone, butanone (i.e., methyl ethyl ketone), methyl isobutyl ketone, cyclohexanone, N-methyl-pyrrolidone, toluene, xylene, methoxyethyl acetate, ethoxyethyl acetate, propoxyethyl acetate, ethyl acetate, propylene glycol methyl ether acetate, dimethyl formamide, dimethyl acetamide, or a mixture thereof.

In addition to the aforementioned maleic anhydride-modified polyolefin, maleimide resin and acrylate monomer (having two or more unsaturated C═C double bonds) and/or its oligomer, the resin composition of the present disclosure may further optionally comprise an organic silicone oil.

For example, in one embodiment, relative to 100 parts by weight of the maleic anhydride-modified polyolefin, the resin composition of the present disclosure may further comprise 1 part by weight to 10 parts by weight of an organic silicone oil, but not limited thereto.

The organic silicone oil comprises, but is not limited to, any one of amino group-modified organic silicone oil, epoxy group-modified organic silicone oil, hydroxyl group-modified organic silicone oil, mercapto group-modified organic silicone oil, carboxyl group-modified organic silicone oil, carboxylic anhydride-modified organic silicone oil, (meth)acrylate group-modified organic silicone oil, methyl hydrogen organic silicone oil, polyether-modified organic silicone oil, aralkyl group-modified organic silicone oil, phenyl group-modified organic silicone oil, long chain alkyl group-modified organic silicone oil, or a combination thereof. For example, in one embodiment, the organic silicone oil is commercially available, such as KF series products and X-22 series products from Shin-Etsu Chemical Co., Ltd., but not limited thereto.

For example, in one embodiment, preferably, the organic silicone oil comprises an unsaturated C═C double bond-containing organic silicone oil. In the unsaturated C═C double bond-containing organic silicone oil, the equivalent of the unsaturated C═C double bonds may be 50 to 4000 g/mol, preferably 150 to 1000 g/mol, but not limited thereto. Preferably, the unsaturated C═C double bond-containing organic silicone oil comprises (meth)acrylate group-modified organic silicone oil and vinyl group-modified organic silicone oil. For example, in one embodiment, (meth)acrylate group-modified organic silicone oil comprises bifunctional (meth)acrylate group-modified organic silicone oil, monofunctional (meth)acrylate group-modified organic silicone oil or a combination thereof.

In addition to the aforesaid components, the resin composition of the present disclosure may further optionally comprise any one of a polyolefin different from the maleic anhydride-modified polyolefin, an unsaturated C═C double bond-containing polyphenylene ether resin, a benzoxazine resin, an epoxy resin, an active ester, a phenol resin, an amine curing agent, a polyamide, a polyimide, a cyanate ester resin or a combination thereof.

For example, in one embodiment, the resin composition of the present disclosure may comprise a polyolefin different from the maleic anhydride-modified polyolefin. For example, relative to 100 parts by weight of the maleic anhydride-modified polyolefin, the resin composition of the present disclosure may contain 1 part by weight to 100 parts by weight of a different polyolefin, but not limited thereto. According to the present disclosure, the type of the polyolefin different from the maleic anhydride-modified polyolefin is not particularly limited and may be any polyolefins known in the field to which this disclosure pertains, and it may be any one or more commercially available products, products prepared by the Applicant or a combination thereof. The conventional polyolefin suitable for the present disclosure comprises, such as but not limited to, any one of polybutadiene, polyisoprene, styrene-butadiene copolymer, styrene-isoprene copolymer, styrene-butadiene-divinylbenzene polymer, vinyl-polybutadiene-urethane polymer, polymethylstyrene, hydrogenated polybutadiene, hydrogenated polyisoprene, hydrogenated styrene-butadiene-divinylbenzene polymer, hydrogenated styrene-butadiene copolymer, hydrogenated styrene-isoprene copolymer, epoxy group-containing polybutadiene, ethylvinylbenzene-divinylbenzene-styrene copolymer and vinyl-divinylbenzene-styrene copolymer, or a combination thereof.

For example, in one embodiment, the resin composition of the present disclosure may further optionally comprise any one of an unsaturated C═C double bond-containing polyphenylene ether resin, a benzoxazine resin, an epoxy resin, an active ester, a phenol resin, an amine curing agent, a polyamide, a polyimide, a cyanate ester resin or a combination thereof.

Unless otherwise specified, in the resin composition of the present disclosure, relative to 100 parts by weight of the maleic anhydride-modified polyolefin, the amount of an unsaturated C═C double bond-containing polyphenylene ether resin, a benzoxazine resin, an epoxy resin, an active ester, a phenol resin, a polyamide, a polyimide or a cyanate ester resin is not particularly limited and may for example range from 1 part by weight to 100 parts by weight, such as but not limited to 1 part by weight, 10 parts by weight, 15 parts by weight, 20 parts by weight, 25 parts by weight, 50 parts by weight or 100 parts by weight. Relative to 100 parts by weight of the maleic anhydride-modified polyolefin, the amount of an amine curing agent is also not particularly limited and may for example range from 1 to 15 parts by weight, such as but not limited to 1 part by weight, 4 parts by weight, 7.5 parts by weight, 12 parts by weight or 15 parts by weight.

According to the present disclosure, for example, the unsaturated C═C double bond-containing polyphenylene ether resin suitable for the present disclosure is not particularly limited and may be any unsaturated C═C double bond-containing polyphenylene ether resins known in the field to which this disclosure pertains, and it may be any one or more commercial products, products prepared by the Applicant or a combination thereof, such as but not limited to any one of vinylbenzyl group-containing polyphenylene ether resin, (meth)acryloyloxy group-containing polyphenylene ether resin and vinyl group-containing polyphenylene ether resin or a combination thereof. The unsaturated C═C double bond-containing polyphenylene ether resin of the present disclosure has an unsaturated C═C double bond and a phenylene ether skeleton, wherein the unsaturated C═C double bond is a reactive group which may perform self-polymerization under heat and may also perform free radical polymerization with other components containing an unsaturated bond in the resin composition and finally result in crosslinking and curing. Preferably, the unsaturated C═C double bond-containing polyphenylene ether resin comprises an unsaturated C═C double bond-containing polyphenylene ether resin with 2,6-dimethyl substitution in its phenylene ether skeleton, wherein the methyl groups form steric hindrance to prevent the oxygen atom of the ether group from forming a hydrogen bond or Van der Waals force to absorb moisture.

For example, in one embodiment, the unsaturated C═C double bond-containing polyphenylene ether resin comprises, but not limited to, a vinylbenzyl group-containing polyphenylene ether resin with a number average molecular weight of about 1200 (such as OPE-2st 1200, available from Mitsubishi Gas Chemical Co., Inc.), a vinylbenzyl group-containing polyphenylene ether resin with a number average molecular weight of about 2200 (such as OPE-2st 2200, available from Mitsubishi Gas Chemical Co., Inc.), a vinylbenzyl group-containing polyphenylene ether resin with a number average molecular weight of about 2400 to 2800 (such as a vinylbenzyl group-containing bisphenol A polyphenylene ether resin), a (meth)acryloyloxy group-containing polyphenylene ether resin with a number average molecular weight of about 1900 to 2300 (such as SA9000, available from Sabic), a vinyl group-containing polyphenylene ether resin with a number average molecular weight of about 2200 to 3000, or a combination thereof. The vinyl group-containing polyphenylene ether resin may include various polyphenylene ether resins disclosed in the US Patent Application Publication No. 20160185904A1, all of which are incorporated herein by reference in their entirety. For example, in one embodiment, the vinylbenzyl group-containing polyphenylene ether resin comprises, but not limited to, a vinylbenzyl group-containing biphenyl polyphenylene ether resin, a vinylbenzyl group-containing bisphenol A polyphenylene ether resin or a combination thereof.

According to the present disclosure, for example, the benzoxazine resin may be any benzoxazine resins known in the field to which this disclosure pertains. Examples include but are not limited to bisphenol A benzoxazine resin, bisphenol F benzoxazine resin, phenolphthalein benzoxazine resin, dicyclopentadiene benzoxazine resin, phosphorus-containing benzoxazine resin, diamino benzoxazine resin and phenyl group-modified, vinyl group-modified or allyl group-modified benzoxazine resin or a combination thereof. Commercially available products include LZ-8270 (phenolphthalein benzoxazine resin), LZ-8298 (phenolphthalein benzoxazine resin), LZ-8280 (bisphenol F benzoxazine resin) and LZ-8290 (bisphenol A benzoxazine resin) available from Huntsman, and KZH-5031 (vinyl group-modified benzoxazine resin) and KZH-5032 (phenyl group-modified benzoxazine resin) available from Kolon Industries Inc. The diamino benzoxazine resin may be diaminodiphenylmethane benzoxazine resin, diaminodiphenyl ether benzoxazine resin, diaminodiphenyl sulfone benzoxazine resin, diaminodiphenyl sulfide benzoxazine resin or a combination thereof, but not limited thereto.

According to the present disclosure, for example, the epoxy resin may be any epoxy resins known in the field to which this disclosure pertains. In terms of improving the thermal resistance of the resin composition, the epoxy resin may include, but not limited to, any one of bisphenol A epoxy resin, bisphenol F epoxy resin, bisphenol S epoxy resin, bisphenol AD epoxy resin, novolac epoxy resin, trifunctional epoxy resin, tetrafunctional epoxy resin, multifunctional novolac epoxy resin, dicyclopentadiene (DCPD) epoxy resin, phosphorus-containing epoxy resin, p-xylene epoxy resin, naphthalene epoxy resin (e.g., naphthol epoxy resin), benzofuran epoxy resin, isocyanate-modified epoxy resin, or a combination thereof. According to the present disclosure, for example, the novolac epoxy resin may be phenol novolac epoxy resin, bisphenol A novolac epoxy resin, bisphenol F novolac epoxy resin, biphenyl novolac epoxy resin, phenol benzaldehyde epoxy resin, phenol aralkyl novolac epoxy resin or o-cresol novolac epoxy resin. According to the present disclosure, for example, the phosphorus-containing epoxy resin may be DOPO (9,10-dihydro-9-oxa-10-phosphaphenanthrene-10-oxide) epoxy resin, DOPO-HQ epoxy resin or a combination thereof. The DOPO epoxy resin may be any one or more selected from DOPO-containing phenol novolac epoxy resin, DOPO-containing o-cresol novolac epoxy resin and DOPO-containing bisphenol-A novolac epoxy resin. The DOPO-HQ epoxy resin may be any one or more selected from DOPO-HQ-containing phenol novolac epoxy resin, DOPO-HQ-containing o-cresol novolac epoxy resin and DOPO-HQ-containing bisphenol-A novolac epoxy resin, but not limited thereto.

The active ester suitable for the resin composition of the present disclosure may be any active polyester resins known in the field to which this disclosure pertains, including but not limited to various commercially available active polyester resin products. Examples include but are not limited to a dicyclopentadiene-containing polyester resin and a naphthalene-containing polyester resin, such as but not limited to active polyester resin products HPC-8000 and HPC-8150 available from D.I.C. Corporation.

According to the present disclosure, for example, the phenol resin may be any phenol resins known in the field to which this disclosure pertains. Examples include but are not limited to novolac resin or phenoxy resin, wherein the novolac resin includes at least one of phenol novolac resin, o-cresol novolac resin, bisphenol A novolac resin, naphthol novolac resin, biphenyl novolac resin and dicyclopentadiene phenol resin or a combination thereof, but not limited thereto.

According to the present disclosure, for example, the amine curing agent may be any amine curing agents known in the field to which this disclosure pertains. Examples include but are not limited to any one or a combination of diamino diphenyl sulfone, diamino diphenyl methane, diamino diphenyl ether, diamino diphenyl sulfide and dicyandiamide.

According to the present disclosure, for example, the polyamide may be any polyamides known in the field to which this disclosure pertains. Examples include but are not limited to various commercially available polyamide resin products.

According to the present disclosure, for example, the polyimide may be any polyimides known in the field to which this disclosure pertains. Examples include but are not limited to various commercially available polyimide resin products.

According to the present disclosure, for example, the cyanate ester resin may be any cyanate ester resins known in the field to which this disclosure pertains, such as a compound having an Ar—O—C═N structure, wherein Ar may be a substituted or unsubstituted aromatic group. In terms of improving the thermal resistance of the resin composition, examples include but are not limited to novolac cyanate ester resin, bisphenol A cyanate ester resin, bisphenol F cyanate ester resin, dicyclopentadiene-containing cyanate ester resin, naphthalene-containing cyanate ester resin, phenolphthalein cyanate ester resin, adamantane cyanate ester resin, fluorene cyanate ester resin or a combination thereof. The novolac cyanate ester resin may be bisphenol A novolac cyanate ester resin, bisphenol F novolac cyanate ester resin or a combination thereof. For example, the cyanate ester resin may be available under the product name Primaset PT-15, PT-30S, PT-60S, BA-200, BA-230S, BA-3000S, BTP-2500, BTP-6020S, DT-4000, DT-7000, ULL950S, HTL-300, CE-320, LVT-50, or LeCy sold by Lonza.

In addition to the aforesaid components, the resin composition of the present disclosure may further optionally comprise any one of an inorganic filler, a flame retardant, a curing accelerator, a polymerization inhibitor, a coloring agent, a surfactant, a toughening agent or a combination thereof.

According to the present disclosure, for example, the inorganic filler may be any inorganic fillers known in the field to which this disclosure pertains, examples thereof including but not limited to silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride, zirconium tungstate, petalite, calcined kaolin or a combination thereof. Moreover, the inorganic filler can be spherical (including solid sphere or hollow sphere), fibrous, plate-like, particulate, flake-like or whisker-like and can be optionally pretreated by a silane coupling agent. For example, in one embodiment, relative to 100 parts by weight of the maleic anhydride-modified polyolefin, the resin composition of the present disclosure may further comprise 10 parts by weight to 500 parts by weight of an inorganic filler, preferably 50 parts by weight to 400 parts by weight of an inorganic filler, more preferably 150 parts by weight to 350 parts by weight of an inorganic filler, but not limited thereto.

According to the present disclosure, for example, the flame retardant may be any flame retardants known in the field to which this disclosure pertains, such as but not limited to a phosphorus-containing flame retardant or a bromine-containing flame retardant. The bromine-containing flame retardant preferably comprises decabromodiphenyl ethane, and the phosphorus-containing flame retardant preferably comprises: hydroquinone bis-(diphenyl phosphate), bisphenol A bis-(diphenylphosphate), tri(2-carboxyethyl) phosphine (TCEP), phosphoric acid tris(chloroisopropyl) ester, trimethyl phosphate (TMP), dimethyl methyl phosphonate (DMMP), resorcinol bis(dixylenyl phosphate) (RDXP, such as commercially available PX-200, PX-201 and PX-202), ammonium polyphosphate, melamine polyphosphate, DPPO (diphenylphosphine oxide) and its derivatives (such as di-DPPO compounds) or resins, melamine cyanurate, tri-hydroxy ethyl isocyanurate, aluminium phosphinate (e.g., commercially available OP-930 and OP-935) or a combination thereof.

For example, in one embodiment, the flame retardant may be a flame retardant commercially available from Katayama Chemical Industries Co., Ltd., such as but not limited to V1, V2, V3, V4, V5, V7, S-2, S-4, E-4c, E-7c, E-8g, E-9g, E-10g, E-100, B-3, W-10, W-2h, W-20, W-30, W-40, OX-1, OX-2, OX-4, OX-6, OX-6+, OX-7, OX-7+, OX-13, BPE-1, BPE-3, HyP-2, API-9, CMPO, ME-20, C-1R, C-1S, C-3R, C-3S or C-11R. The flame retardant of the present disclosure may include one or more of the above flame retardants. For example, unless otherwise specified, relative to 100 parts by weight of the maleic anhydride-modified polyolefin, the resin composition of the present disclosure may further comprise 1 part by weight to 100 parts by weight of a flame retardant, preferably 1 part by weight to 50 parts by weight of a flame retardant, but not limited thereto.

According to the present disclosure, for example, the curing accelerator may comprise a catalyst, such as a Lewis base or a Lewis acid. The Lewis base may comprise any one or more of imidazole, boron trifluoride-amine complex, ethyltriphenyl phosphonium chloride, 2-methylimidazole (2 MI), 2-phenyl-1H-imidazole (2PZ), 2-ethyl-4-methylimidazole (2E4MZ), triphenylphosphine (TPP) and 4-dimethylaminopyridine (DMAP). The Lewis acid may comprise metal salt compounds, such as those of manganese, iron, cobalt, nickel, copper and zinc, such as zinc octanoate or cobalt octanoate. The curing accelerator also includes a curing initiator, such as a peroxide capable of producing free radicals. The curing initiator comprises but is not limited to: dicumyl peroxide (DCP), t-butyl peroxybenzoate, dibenzoyl peroxide (BPO), 2,5-dimethyl-2,5-di(t-butylperoxy)-3-hexyne (25B), bis(t-butylperoxyisopropyl)benzene or a combination thereof. For example, in one embodiment, relative to 100 parts by weight of the maleic anhydride-modified polyolefin, the resin composition of the present disclosure may further comprise 0.001 part by weight to 20 parts by weight of a curing accelerator, preferably 0.01 part by weight to 15 parts by weight of a curing accelerator, more preferably 1 part by weight to 10 parts by weight of a curing accelerator, but not limited thereto.

According to the present disclosure, for example, the polymerization inhibitor may comprise, but not limited to, 1,1-diphenyl-2-picrylhydrazyl radical, methyl acrylonitrile, nitroxide-mediated radical, triphenylmethyl radical, metal ion radical, sulfur radical (such as including but not limited to dithioester), hydroquinone, 4-methoxyphenol, p-benzoquinone, phenothiazine, β-phenylnaphthylamine, 4-t-butylcatechol, methylene blue, 4,4′-butylidenebis(6-t-butyl-3-methylphenol) and 2,2′-methylenebis(4-ethyl-6-t-butylphenol) or a combination thereof. For example, the nitroxide-mediated radical may comprise, but not limited to, nitroxide radicals derived from cyclic hydroxylamines, such as 2,2,6,6-tetramethyl-1-oxo-piperidine, 2,2,6,6-substituted piperidine 1-oxyl free radical, 2,2,5,5-substituted pyrrolidine 1-oxyl free radical or the like. Preferred substitutes include alkyl groups with 4 or fewer carbon atoms, such as methyl group or ethyl group. Examples of the compound containing a nitroxide radical include but are not limited to 2,2,6,6-tetramethylpiperidine 1-oxyl free radical, 2,2,6,6-tetraethylpiperidine 1-oxyl free radical, 2,2,6,6-tetramethyl-4-oxo-piperidine 1-oxyl free radical, 2,2,5,5-tetramethylpyrrolidine 1-oxyl free radical, 1,1,3,3-tetramethyl-2-isoindoline oxygen radical, N,N-di-tert-butylamine oxygen free radical and so on. Nitroxide radicals may also be replaced by using stable radicals such as galvinoxyl radicals. The polymerization inhibitor suitable for the resin composition of the present disclosure may include products derived from the polymerization inhibitor with its hydrogen atom or group substituted by other atom or group. Examples include products derived from a polymerization inhibitor with its hydrogen atom substituted by an amino group, a hydroxyl group, a carbonyl group or the like. For example, in one embodiment, relative to 100 parts by weight of the maleic anhydride-modified polyolefin, the resin composition of the present disclosure may further comprise 0.001 part by weight to 20 parts by weight of a polymerization inhibitor, preferably 0.001 part by weight to 10 parts by weight of a polymerization inhibitor, but not limited thereto.

According to the present disclosure, for example, the coloring agent may comprise but is not limited to dye or pigment. For example, in one embodiment, relative to 100 parts by weight of the maleic anhydride-modified polyolefin, the resin composition of the present disclosure may further comprise 0.001 part by weight to 10 parts by weight of a coloring agent, preferably 0.01 part by weight to 5 parts by weight of a coloring agent, but not limited thereto.

The type of the surfactant suitable for the resin composition of the present disclosure is not particularly limited. The purpose of surfactant used herein is to ensure uniform distribution of the filler in the resin composition. For example, in one embodiment, relative to 100 parts by weight of the maleic anhydride-modified polyolefin, the resin composition of the present disclosure may further comprise 0.001 part by weight to 10 parts by weight of a surfactant, preferably 0.01 part by weight to 5 parts by weight of a surfactant, but not limited thereto.

According to the present disclosure, the main purpose of adding a toughening agent is to improve the toughness of the resin composition. For example, the toughening agent suitable for the present disclosure may comprise, but not limited to, carboxyl-terminated butadiene acrylonitrile rubber (CTBN rubber), core-shell rubber, ethylene propylene rubber or a combination thereof. For example, in one embodiment, relative to 100 parts by weight of the maleic anhydride-modified polyolefin, the resin composition of the present disclosure may further comprise 1 part by weight to 20 parts by weight of a toughening agent, preferably 3 parts by weight to 10 parts by weight of a toughening agent, but not limited thereto.

For example, in one embodiment, the resin composition of various embodiments may be processed to make different articles, such as those suitable for use as components in electronic products, including but not limited to a prepreg, a resin film, a laminate or a printed circuit board.

For example, the resin composition of the present disclosure can be used to make a prepreg, which comprises a reinforcement material and a layered structure disposed thereon. The layered structure is formed by heating the resin composition at a high temperature to the B-stage. Suitable baking temperature for making a prepreg may be for example 120° C. to 180° C., preferably 120° C. to 160° C. For example, the reinforcement material may be any one of a fiber material, woven fabric, and non-woven fabric, and the woven fabric preferably comprises fiberglass fabrics. The type of the fiberglass fabric is not particularly limited and may be any fiberglass fabrics used for a printed circuit board, such as E-glass fabric, D-glass fabric, S-glass fabric, T-glass fabric, L-glass fabric, Q-glass fabric or QL-glass fabric (glass fabric with hybrid structure made of Q-glass and L-glass). The fiber may comprise yarns and rovings, in spread form or standard form, and the shape of terminal face may be round or flat. Non-woven fabric preferably comprises liquid crystal polymer non-woven fabric, such as polyester non-woven fabric, polyurethane non-woven fabric and so on, but not limited thereto. Woven fabric may also comprise liquid crystal polymer woven fabric, such as polyester woven fabric, polyurethane woven fabric and so on, but not limited thereto. The reinforcement material may increase the mechanical strength of the prepreg. In one preferred embodiment, the reinforcement material can also be optionally pre-treated by a silane coupling agent. The prepreg may be further heated and cured to the C-stage to form an insulation layer.

For example, the resin composition from each embodiment of the disclosure can be used to make a resin film, which is prepared by heating and baking to semi-cure (B-stage) the resin composition. The resin composition may be selectively coated on a liquid crystal polymer film, a polytetrafluoroethylene film (PTFE film), a polyethylene terephthalate film (PET film), a polyimide film (PI film), a copper foil (including but not limited to a 1-ounce (oz) hyper very low profile (HVLP) copper foil with a thickness of 28 mil) or a resin-coated copper (RCC), followed by heating and baking to semi-cure the resin composition to form the resin film.

For example, the resin composition from each embodiment of the present disclosure can be made into a laminate, which comprises at least two metal foils and at least one insulation layer disposed between the metal foils, wherein the insulation layer is made by curing the resin composition at high temperature and high pressure to the C-stage, a suitable curing temperature being for example between 190° C. and 220° C. and preferably between 200° C. and 210° C., a suitable curing time being 90 to 180 minutes and preferably 120 to 150 minutes, and a suitable lamination pressure being for example between 300 psi and 550 psi and preferably between 400 psi and 500 psi. The insulation layer may be obtained by curing the aforesaid prepreg or resin film. The metal foil may contain copper, aluminum, nickel, platinum, silver, gold or alloy thereof, such as a copper foil (including but not limited to a 1-ounce (oz) hyper very low profile (HVLP) copper foil with a thickness of 28 mil). In a preferred embodiment, the laminate is a copper-clad laminate.

In one embodiment, the laminate may be further processed by trace formation processes to obtain a printed circuit board. In one embodiment of making a printed circuit board, a double-sided copper-clad laminate (such as product EM-891, available from Elite Material Co., Ltd.) with a thickness of 28 mil and having 1 ounce (oz) HVLP (hyper very low profile) copper foils may be used, which is subject to drilling and then electroplating, so as to form electrical conduction between the top layer copper foil and the bottom layer copper foil. Then the top layer copper foil and the bottom layer copper foil are etched to form an inner layer circuit board. Then brown oxidation and roughening are performed on the inner layer circuit board to form uneven structures on the surface to increase roughness. Next, a vacuum lamination apparatus is used to laminate the assembly of a copper foil, the prepreg, the inner layer circuit board, the prepreg and a copper foil stacked in said order by heating at 190° C. to 245° C. for 90 to 240 minutes to cure the insulation material of the prepregs. Next, black oxidation, drilling, copper plating and other known circuit board processes are performed on the outmost copper foils so as to obtain the printed circuit board.

For example, in one embodiment, an article made from the resin composition from each embodiment contains a cured product obtained by curing the resin composition.

For example, in one embodiment, the article solely contains a cured product obtained by curing the resin composition. For example, in one embodiment, the article contains a cured product obtained by curing the resin composition and a support material. The support material comprises but is not limited to a liquid crystal polymer film, a polytetrafluoroethylene film (PTFE film), a polyethylene terephthalate film (PET film), a polyimide film (PI film) or a metal foil.

For example, in one embodiment, the present disclosure provides an article containing a cured product obtained by curing completely the resin composition through a heating process to the C-stage. In the heating process, a suitable curing temperature may be for example between 150° C. and 250° C., preferably between 190° C. and 220° C., and a curing time may be 90 to 240 minutes, preferably 120 to 180 minutes. For example, the shape of the cured product is not particularly limited and may be in the form of layers, blocks, particles, etc. For example, the preparation method of the cured product is not particularly limited, and the cured product may be obtained by placing the resin composition in a mold with specific shape and heating to completely cure the resin composition. The mold with specific shape includes but is not limited to a laminate with a groove, an electroplated hole of a printed circuit board or a circuit open area of a printed circuit board; it can also be obtained by coating the resin composition on a support material and heating to cure the resin composition completely.

In one embodiment, the present disclosure also provides a use of the above-mentioned resin composition in a printed circuit board hole-plugging process (also known as resin plugging). For example, in a printed circuit board fabrication process, a double-sided copper-clad laminate is first drilled, and then electroplated to form electrical conduction between the upper copper foil and the bottom copper foil, followed by a hole-plugging process. The resin composition of the present disclosure is particularly suitable for a printed circuit board hole-plugging process. The resin composition of the present disclosure can be plugged into holes and cured completely, followed by various circuit board processes known in the field to which this disclosure pertains.

In one embodiment, the present disclosure also provides a use of the above-mentioned resin composition in a printed circuit board circuit filling process (also known as resin filling). For example, in a printed circuit board fabrication process, a double-sided copper-clad laminate is first drilled, and then electroplated to form electrical conduction between the upper copper foil and the bottom copper foil, followed by hole-plugging process. Then the upper copper foil and the bottom copper foil were etched to form an inner layer circuit board, and a circuit filling process is selectively performed according to the thickness of copper of the inner layer circuit board. The resin composition of the present disclosure is particularly suitable for a printed circuit board circuit filling process. The resin composition of the present disclosure can be filled into a circuit open area (i.e., an area without circuits) and cured completely, followed by various circuit board processes known in the field to which this disclosure pertains.

For example, in one embodiment, the resin composition disclosed herein or various articles with cured products made therefrom may preferably have any one, more or all of the following properties:
a varnish shelf life of the resin composition being greater than 90 days, such as between 91 and 180 days, such as a varnish shelf life of 91, 100, 110, 120, 130, 140, 150, 160, 170 or 180 days;
a percent of organic volatile matters of the resin composition as measured by reference to IPC-TM-650 2.4.24.6 of less than or equal to 0.5%, such as between 0.1% and 0.5%;
a dissipation factor at 10 GHz as measured by reference to JIS C2565 of less than or equal to 0.0038, such as between 0.0034 and 0.0038;
a glass transition temperature as measured by reference to IPC-TM-650 2.4.24.5 of greater than or equal to 160° C., such as between 160° C. and 214° C.;
a percent of thermal expansion in Z-axis as measured by reference to IPC-TM-650 2.4.24.5 of less than or equal to 1.6%, such as between 0.9% and 1.6%;
a copper foil peeling strength as measured by reference to IPC-TM-650 2.4.8 of greater than or equal to 4.5 lb/in, such as between 4.5 lb/in and 6.9 lb/in;
a water absorption ratio as measured by reference to IPC-TM-650 2.6.2.1 and IPC-TM-650 2.6.16.1 of less than or equal to 0.60%, such as between 0.51% and 0.60%; and
a percent of cure shrinkage as measured and calculated by reference to GB/T4472-2011 of less than or equal to 6.0%, such as between 3.9% and 6.0%.

Raw materials below were used to prepare the resin compositions of various Examples and Comparative Examples of the present disclosure according to the amount listed in Table 1 to Table 6 and further fabricated to prepare test samples.

Materials and reagents used in Examples and Comparative Examples disclosed herein are listed below:
A1: maleic anhydride-adducted polybutadiene, having an anhydride equivalent of 1981 g/eq., commercially available.
A2: maleic anhydride-adducted polybutadiene, having an anhydride equivalent of 1238 g/eq., commercially available.
A3: maleic anhydride-adducted polybutadiene, having an anhydride equivalent of 762 g/eq., commercially available.
A4: maleic anhydride-adducted polybutadiene, having an anhydride equivalent of 981 g/eq., commercially available.
A5: maleic anhydride-adducted polybutadiene, having an anhydride equivalent of 583 g/eq., commercially available.
A6: maleic anhydride-adducted styrene-butadiene copolymer, having an anhydride equivalent of 1651 g/eq., commercially available.
A7: maleic anhydride-styrene copolymer, having an anhydride equivalent of 900 to 950 g/eq., commercially available.
Ricon 130: polybutadiene, available from Cray Valley.
G1726: hydrogenated styrene-butadiene-styrene block copolymer, available from Kraton Polymers.
SBS-A: styrene-butadiene copolymer, which is a styrene-butadiene-styrene triblock copolymer, available from Nippon Soda.

Maleimide of Formula (1): commercially available, wherein each R1 is a methyl group, each m1 is 2, n1 is 0, and p1 is a value from 0.5 to 20.

Maleimide of Formula (2): commercially available, wherein p2 is a value from 1 to 10.

Maleimide of Formula (3): commercially available, wherein p3 is a value from 1 to 10. BMI-5100: 3,3′-dimethyl-5,5′-diethyl-4,4′-diphenylmethane bismaleimide, as shown below, available from Daiwakasei Industry Co., Ltd.

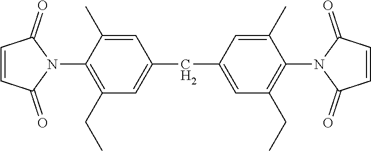 [SMILES: CCc1cc(Cc2cc(C)c(N3C(=O)C=CC3=O)c(CC)c2)cc(C)c1N1C(=O)C=CC1=O]

BMI-2300: polyphenylmethane maleimide, as shown below, wherein p4 is a value from 1 to 10, available from Daiwakasei Industry Co., Ltd.

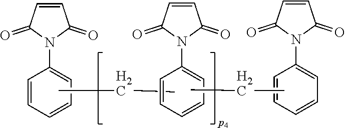

BMI-4000: bisphenol A diphenyl ether bismaleimide, as shown below, available from Daiwakasei Industry Co., Ltd.

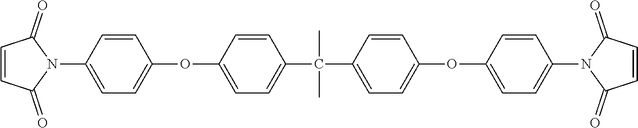 [SMILES: CC(C)(c1ccc(Oc2ccc(N3C(=O)C=CC3=O)cc2)cc1)c1ccc(Oc2ccc(N3C(=O)C=CC3=O)cc2)cc1]

BMI-1000: 4,4′-diphenylmethane bismaleimide, as shown below, available from Daiwakasei Industry Co., Ltd.

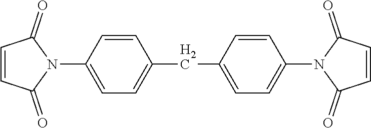 [SMILES: O=C1C=CC(=O)N1c1ccc(Cc2ccc(N3C(=O)C=CC3=O)cc2)cc1]

BMI-1500: maleimide containing aliphatic structure with 10 to 50 carbon atoms, as shown below, wherein p₅ is a value from 1 to 10, available from Designer Molecules Inc.

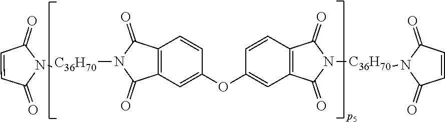

BMI-3000: maleimide containing aliphatic structure with 10 to 50 carbon atoms, as shown below, wherein p6 is a value from 1 to 10, available from Designer Molecules Inc.

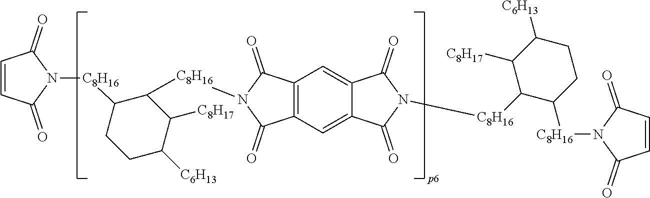

BMI-1700: maleimide containing aliphatic structure with 10 to 50 carbon atoms, as shown below, wherein p7 is a value from 1 to 10, available from Designer Molecules Inc.

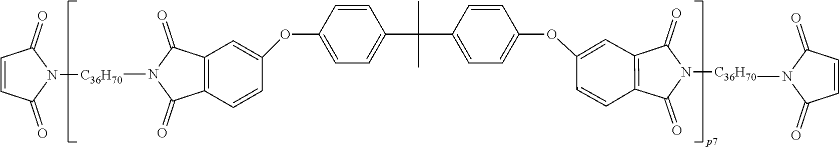

SR833S: tricyclodecane dimethanol diacrylate, as shown below, available from Sartomer, its cured product having a glass transition temperature of about 180° C.

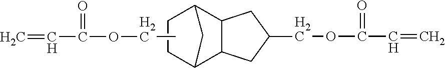

SR368NS: tris(2-hydroxyethyl) isocyanurate triacrylate, as shown below, available from Sartomer, its cured product having a glass transition temperature of about 272° C.

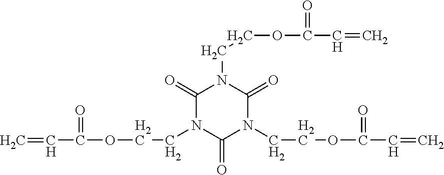 [SMILES: C=CC(=O)OCCn1c(=O)n(CCOC(=O)C=C)c(=O)n(CCOC(=O)C=C)c1=O]

Oligomer of SR833S: oligomer of tricyclodecane dimethanol diacrylate, obtained by subjecting tricyclodecane dimethanol diacrylate to a polymerization reaction, having a weight average molecular weight of less than 2000, its cured product having a glass transition temperature of about 180° C.

SR295 NS: pentaerythritol tetraacrylate, as shown below, available from Sartomer, its cured product having a glass transition temperature of about 103° C.

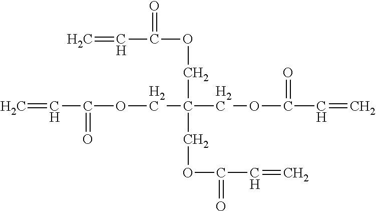 [SMILES: C=CC(=O)OCC(COC(=O)C=C)(COC(=O)C=C)COC(=O)C=C]

SR399 NS: dipentaerythritol pentaacrylate, as shown below, available from Sartomer, its cured product having a glass transition temperature of about 90° C.

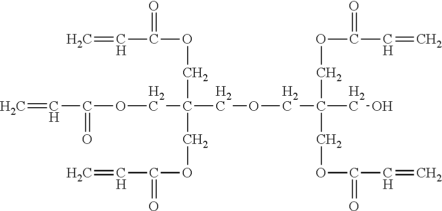 [SMILES: C=CC(=O)OCC(CO)(COCC(COC(=O)C=C)(COC(=O)C=C)COC(=O)C=C)COC(=O)C=C]

DPHA: dipentaerythritol hexaacrylate, as shown below, available from Sartomer, its cured product having a glass transition temperature of about 90° C.

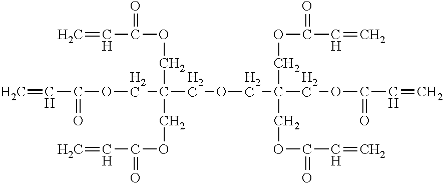 [SMILES: C=CC(=O)OCC(COCC(COC(=O)C=C)(COC(=O)C=C)COC(=O)C=C)(COC(=O)C=C)COC(=O)C=C]

SR420:3,3,5-trimethylcyclohexane acrylate, which is a mono-functional acrylate, as shown below, available from Sartomer, its cured product having a glass transition temperature of about 81° C.

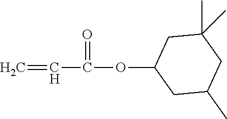

SG-P3: acrylate elastomer (a polymer with high molecular weight, different from the oligomer of acrylate monomer), having a weight average molecular weight of 850,000, which is an epoxy group-containing acrylic polymer, available from Nagase ChemteX Corporation.

PMS-22-1: acrylate elastomer (a polymer with high molecular weight, different from the oligomer of acrylate monomer), having a weight average molecular weight of 100,000, available from Nagase ChemteX Corporation.

X-22-164: methacrylate group-modified organic silicone oil, having a methacrylate equivalent of 190 g/mol, available from Shin-Etsu Chemical Co., Ltd.

X-22-164AS: methacrylate group-modified organic silicone oil, having a methacrylate equivalent of 450 g/mol, available from Shin-Etsu Chemical Co., Ltd.

X-22-164A: methacrylate group-modified organic silicone oil, having a methacrylate equivalent of 860 g/mol, available from Shin-Etsu Chemical Co., Ltd.

KF99: methyl hydrogen organic silicone oil, not containing unsaturated C═C double bonds, having a hydrogen equivalent of 60 g/mol, available from Shin-Etsu Chemical Co., Ltd.

DCP: dicumyl peroxide, available from NOF Corporation.

SC-2500-SVJ: spherical silica, available from Admatechs.

Compositions and test results of resin compositions of Examples and Comparative Examples used herein are listed in Table 1 to Table 6:

TABLE 1
Resin compositions of Examples (in part by weight) and test results

| Component | | E1 | E2 | E3 | E4 | E5 | E6 |
|---|---|---|---|---|---|---|---|
| maleic | A1 | | | | | 100 | |
| anhydride-modified | A2 | 100 | 100 | 100 | 100 | | 100 |
| polyolefin | A3 | | | | | | |
| | A4 | | | | | | |
| | A5 | | | | | | |
| | A6 | | | | | | |
| | A7 | | | | | | |
| maleimide resin | maleimide of Formula (1) | | | | | | |
| | maleimide of Formula (2) | 5 | 40 | 25 | 25 | 25 | |
| | maleimide of Formula (3) | | | | | | |
| | BMI-5100 | | | | | | |
| | BMI-2300 | | | | | | 25 |
| | BMI-4000 | | | | | | |
| | BMI-1000 | | | | | | |
| | BMI-1500 | | | | | | |
| | BMI-3000 | | | | | | |
| | BMI-1700 | | | | | | |
| acrylate monomer | SR833S | 60 | 60 | 30 | 90 | 60 | 60 |
| or its oligomer | SR368NS | | | | | | |
| | oligomer of SR833S | | | | | | |
| | SR295 NS | | | | | | |
| | SR399 NS | | | | | | |
| | DPHA | | | | | | |
| organic silicone oil | X-22-164 | | | | | | |
| | X-22-164AS | | | | | | |
| | X-22-164A | | | | | | |
| | KF99 | | | | | | |
| curing accelerator | DCP | 6 | 6 | 6 | 6 | 6 | 6 |
| inorganic filler | SC-2500-SVJ | 270 | 270 | 270 | 270 | 270 | 270 |

| Item | Unit | E1 | E2 | E3 | E4 | E5 | E6 |
|---|---|---|---|---|---|---|---|
| varnish shelf life | day | >90 | >90 | >90 | >90 | >90 | >90 |
| percent of organic | % | 0.4 | 0.3 | 0.2 | 0.5 | 0.3 | 0.3 |
| volatile matters | | | | | | | |
| dissipation factor | none | 0.0038 | 0.0034 | 0.0035 | 0.0038 | 0.0036 | 0.0038 |
| glass transition | ° C. | 178 | 198 | 175 | 191 | 184 | 190 |
| temperature | | | | | | | |
| percent of thermal | % | 1.3 | 0.9 | 1.4 | 1.1 | 1.2 | 1.0 |
| expansion in Z-axis | | | | | | | |
| copper foil peeling | lb/in | 4.7 | 5.4 | 4.7 | 5.4 | 4.8 | 5.3 |
| strength | | | | | | | |
| water absorption | % | 0.57 | 0.60 | 0.55 | 0.60 | 0.54 | 0.58 |
| ratio | | | | | | | |
| percent of cure | % | 6.0 | 4.5 | 5.8 | 4.1 | 5.1 | 4.9 |
| shrinkage | | | | | | | |

TABLE 2
Resin compositions of Examples (in part by weight) and test results

| Component | | E7 | E8 | E9 | E10 | E11 | E12 |
|---|---|---|---|---|---|---|---|
| maleic | A1 | | | | | | |
| anhydride-modified | A2 | | | | | 100 | 100 |
| polyolefin | A3 | 100 | | | | | |
| | A4 | | 100 | | | | |
| | A5 | | | 100 | | | |
| | A6 | | | | 100 | | |
| | A7 | | | | | | |
| maleimide resin | maleimide of Formula (1) | | 25 | | | | |
| | maleimide of Formula (2) | | | 25 | 25 | | |
| | maleimide of Formula (3) | | | | | 25 | |
| | BMI-5100 | | | | | | 25 |
| | BMI-2300 | | | | | | |
| | BMI-4000 | 25 | | | | | |
| | BMI-1000 | | | | | | |
| | BMI-1500 | | | | | | |
| | BMI-3000 | | | | | | |
| | BMI-1700 | | | | | | |
| acrylate monomer | SR833S | 60 | 60 | 60 | 60 | 60 | 60 |
| or its oligomer | SR368NS | | | | | | |
| | oligomer of SR833S | | | | | | |
| | SR295 NS | | | | | | |
| | SR399 NS | | | | | | |
| | DPHA | | | | | | |
| organic silicone oil | X-22-164 | | | | | | |
| | X-22-164AS | | | | | | |
| | X-22-164A | | | | | | |
| | KF99 | | | | | | |
| curing accelerator | DCP | 6 | 6 | 6 | 6 | 6 | 6 |
| inorganic filler | SC-2500-SVJ | 270 | 270 | 270 | 270 | 270 | 270 |

| Item | Unit | E7 | E8 | E9 | E10 | E11 | E12 |
|---|---|---|---|---|---|---|---|
| varnish shelf life | day | >90 | >90 | >90 | >90 | >90 | >90 |
| percent of organic | % | 0.3 | 0.3 | 0.3 | 0.3 | 0.3 | 0.3 |
| volatile matters | | | | | | | |
| dissipation factor | none | 0.0037 | 0.0034 | 0.0038 | 0.0035 | 0.0038 | 0.0036 |
| glass transition | ° C. | 188 | 180 | 183 | 183 | 185 | 186 |
| temperature | | | | | | | |
| percent of thermal | % | 1.1 | 1.4 | 1.3 | 1.3 | 1.3 | 1.2 |
| expansion in Z-axis | | | | | | | |
| copper foil peeling | lb/in | 5.2 | 4.8 | 5.7 | 5.4 | 5.3 | 4.7 |
| strength | | | | | | | |
| water absorption | % | 0.55 | 0.51 | 0.57 | 0.55 | 0.57 | 0.56 |
| ratio | | | | | | | |
| percent of cure | % | 4.8 | 5.3 | 4.8 | 5.0 | 4.9 | 5.0 |
| shrinkage | | | | | | | |

TABLE 3
Resin compositions of Examples (in part by weight) and test results

| Component | | E13 | E14 | E15 | E16 | E17 | E18 |
|---|---|---|---|---|---|---|---|
| maleic | A1 | | | | | | |
| anhydride-modified | A2 | 100 | 100 | 100 | 100 | 100 | 100 |
| polyolefin | A3 | | | | | | |
| | A4 | | | | | | |
| | A5 | | | | | | |
| | A6 | | | | | | |
| | A7 | | | | | | |
| maleimide resin | maleimide of Formula (1) | | | | | | |
| | maleimide of Formula (2) | | | 25 | 25 | 25 | 25 |
| | maleimide of Formula (3) | | | | | | |
| | BMI-5100 | | | | | | |
| | BMI-2300 | | | | | | |
| | BMI-4000 | | | | | | |
| | BMI-1000 | | | | | | |
| | BMI-1500 | 25 | | | | | |
| | BMI-3000 | | 15 | | | | |
| | BMI-1700 | | 10 | | | | |
| acrylate monomer | SR833S | 60 | 60 | | | | |
| or its oligomer | SR368NS | | | 60 | | | |
| | oligomer of SR833S | | | | 60 | | |
| | SR295 NS | | | | | 60 | |
| | SR399 NS | | | | | | 60 |
| | DPHA | | | | | | |
| organic silicone oil | X-22-164 | | | | | | |
| | X-22-164AS | | | | | | |
| | X-22-164A | | | | | | |
| | KF99 | | | | | | |
| curing accelerator | DCP | 6 | 6 | 6 | 6 | 6 | 6 |
| inorganic filler | SC-2500-SVJ | 270 | 270 | 270 | 270 | 270 | 270 |

| Item | Unit | E13 | E14 | E15 | E16 | E17 | E18 |
|---|---|---|---|---|---|---|---|
| varnish shelf life | day | >90 | >90 | >90 | >90 | >90 | >90 |
| percent of organic | % | 0.4 | 0.4 | 0.2 | 0.1 | 0.2 | 0.2 |
| volatile matters | | | | | | | |
| dissipation factor | none | 0.0035 | 0.0035 | 0.0035 | 0.0035 | 0.0037 | 0.0037 |
| glass transition | ° C. | 160 | 163 | 214 | 183 | 162 | 160 |
| temperature | | | | | | | |
| percent of thermal | % | 1.6 | 1.6 | 1.0 | 1.4 | 1.5 | 1.6 |
| expansion in Z-axis | | | | | | | |
| copper foil peeling | lb/in | 4.5 | 4.5 | 5.1 | 5.2 | 4.9 | 4.7 |
| strength | | | | | | | |
| water absorption | % | 0.54 | 0.54 | 0.54 | 0.53 | 0.56 | 0.56 |
| ratio | | | | | | | |
| percent of cure | % | 5.6 | 5.4 | 4.0 | 5.0 | 5.7 | 5.9 |
| shrinkage | | | | | | | |

TABLE 4
Resin compositions of Examples (in part by weight) and test results

| Component | | E19 | E20 | E21 | E22 | E23 | E24 |
|---|---|---|---|---|---|---|---|
| maleic | A1 | | | | | | |
| anhydride-modified | A2 | 100 | 100 | 100 | 100 | 70 | 80 |
| polyolefin | A3 | | | | | | |
| | A4 | | | | | | |
| | A5 | | | | | | 10 |
| | A6 | | | | | 30 | |
| | A7 | | | | | | 10 |
| maleimide resin | maleimide of Formula (1) | | | | | | 3 |
| | maleimide of Formula (2) | 25 | 25 | 25 | 25 | 5 | 10 |
| | maleimide of Formula (3) | | | | | | 10 |
| | BMI-5100 | | | | | | 10 |
| | BMI-2300 | | | | | 10 | |
| | BMI-4000 | | | | | 5 | |
| | BMI-1000 | | | | | | 5 |
| | BMI-1500 | | | | | | |
| | BMI-3000 | | | | | | |
| | BMI-1700 | | | | | | |
| acrylate monomer | SR833S | | 60 | 60 | 60 | 20 | 70 |
| or its oligomer | SR368NS | | | | | 20 | |
| | oligomer of SR833S | | | | | | |
| | SR295 NS | | | | | | |
| | SR399 NS | | | | | | |
| | DPHA | 60 | | | | | |
| organic silicone oil | X-22-164 | | 1 | 10 | | | |
| | X-22-164AS | | | | | 2 | |
| | X-22-164A | | | | | | 5 |
| | KF99 | | | | 1 | | |
| curing accelerator | DCP | 6 | 6 | 6 | 6 | 1 | 10 |
| inorganic filler | SC-2500-SVJ | 270 | 270 | 270 | 270 | 150 | 350 |

| Item | Unit | E19 | E20 | E21 | E22 | E23 | E24 |
|---|---|---|---|---|---|---|---|
| varnish shelf life | day | >90 | >90 | >90 | >90 | >90 | >90 |
| percent of organic | % | 0.2 | 0.3 | 0.3 | 0.3 | 0.2 | 0.3 |
| volatile matters | | | | | | | |
| dissipation factor | none | 0.0037 | 0.0036 | 0.0034 | 0.0037 | 0.0037 | 0.0035 |
| glass transition | ° C. | 160 | 188 | 190 | 185 | 181 | 204 |
| temperature | | | | | | | |
| percent of thermal | % | 1.6 | 1.3 | 1.2 | 1.3 | 1.3 | 1.0 |
| expansion in Z-axis | | | | | | | |
| copper foil peeling | lb/in | 4.8 | 6.3 | 6.9 | 6.0 | 6.4 | 6.5 |
| strength | | | | | | | |
| water absorption | % | 0.56 | 0.54 | 0.53 | 0.55 | 0.54 | 0.54 |
| ratio | | | | | | | |
| percent of cure | % | 5.8 | 5.0 | 4.6 | 4.9 | 5.4 | 3.9 |
| shrinkage | | | | | | | |

TABLE 5
Resin compositions of Comparative Examples (in part by weight) and test results

| Component | | C1 | C2 | C3 | C4 | C5 | C6 |
|---|---|---|---|---|---|---|---|
| maleic | A2 | 100 | 100 | 100 | 100 | 100 | |
| anhydride-modified | | | | | | | |
| polyolefin | | | | | | | |
| other polyolefin | Ricon 130 | | | | | | |
| | G1726 | | | | | | |
| | SBS-A | | | | | | |
| maleimide resin | maleimide of | 25 | 25 | 25 | | 50 | 25 |
| | Formula (2) | | | | | | |
| acrylate monomer | SR833S | | 20 | 100 | 60 | 60 | 60 |
| monofunctional | SR420 | | | | | | |
| acrylate | | | | | | | |
| acrylate elastomer | SG-P3 | | | | | | |
| | PMS-22-1 | | | | | | |
| curing accelerator | DCP | 6 | 6 | 6 | 6 | 6 | 6 |
| inorganic filler | SC-2500-SVJ | 270 | 270 | 270 | 270 | 270 | 270 |

| Item | Unit | C1 | C2 | C3 | C4 | C5 | C6 |
|---|---|---|---|---|---|---|---|
| varnish shelf life | day | 1 day, | 1 day, | 75 | 60 | 1 day, | 80 |
| | | precipitate | precipitate | | | precipitate | |
| percent of organic | % | 0.1 | 0.2 | 0.6 | 0.8 | 0.3 | 1.2 |
| volatile matters | | | | | | | |
| dissipation factor | none | 0.0033 | 0.0034 | 0.0040 | 0.0042 | 0.0033 | 0.0053 |
| glass transition | ° C. | 152 | 168 | 195 | 143 | 205 | 202 |
| temperature | | | | | | | |
| percent of thermal | % | 1.9 | 1.5 | 1.1 | 2.2 | 0.9 | 1.0 |
| expansion in Z-axis | | | | | | | |
| copper foil peeling | lb/in | 3.8 | 4.3 | 5.5 | 4.2 | 5.5 | 3.9 |
| strength | | | | | | | |
| water absorption | % | 0.47 | 0.53 | 0.68 | 0.56 | 0.64 | 0.79 |
| ratio | | | | | | | |
| percent of cure | % | 7.2 | 6.3 | 4.0 | 6.8 | 4.1 | 3.8 |
| shrinkage | | | | | | | |

TABLE 6
Resin compositions of Comparative Examples (in part by weight) and test results

| Component | | C7 | C8 | C9 | C10 | C11 | C12 |
|---|---|---|---|---|---|---|---|
| maleic | A2 | | | | 100 | 100 | 100 |
| anhydride-modified | | | | | | | |
| polyolefin | | | | | | | |
| other polyolefin | Ricon 130 | 100 | | | | | |
| | G1726 | | 100 | | | | |
| | SBS-A | | | 100 | | | |
| maleimide resin | maleimide of | 25 | 25 | 25 | 25 | 25 | 25 |
| | Formula (2) | | | | | | |
| acrylate monomer | SR833S | 60 | 60 | 60 | | | |
| monofunctional | SR420 | | | | 60 | | |
| acrylate | | | | | | | |
| acrylate elastomer | SG-P3 | | | | | 60 | |
| | PMS-22-1 | | | | | | 60 |
| curing accelerator | DCP | 6 | 6 | 6 | 6 | 6 | 6 |
| inorganic filler | SC-2500-SVJ | 270 | 270 | 270 | 270 | 270 | 270 |

| Item | Unit | C7 | C8 | C9 | C10 | C11 | C12 |
|---|---|---|---|---|---|---|---|
| varnish shelf life | day | 35 | 1 day, | 1 day, | >90 | 1 day, | 1 day, |
| | | | precipitate | precipitate | | precipitate | precipitate |
| percent of organic | % | 0.9 | 0.7 | 0.6 | 1.5 | 0.2 | 0.2 |
| volatile matters | | | | | | | |
| dissipation factor | none | 0.0035 | 0.0034 | 0.0035 | 0.0041 | 0.0048 | 0.0044 |
| glass transition | ° C. | 189 | 155 | 158 | 150 | 141 | 145 |
| temperature | | | | | | | |
| percent of thermal | % | 1.3 | 2.0 | 1.9 | 2.1 | 2.3 | 2.2 |
| expansion in Z-axis | | | | | | | |
| copper foil peeling | lb/in | 3.4 | 2.8 | 3.0 | 4.4 | 5.5 | 5.2 |
| strength | | | | | | | |
| water absorption | % | 0.54 | 0.53 | 0.54 | 0.65 | 0.85 | 0.76 |
| ratio | | | | | | | |
| percent of cure | % | 4.8 | 7.1 | 6.9 | 7.5 | 8.6 | 8.3 |
| shrinkage | | | | | | | |

According to the present disclosure, for the property tests of Examples and Comparative Examples, samples (specimens) were prepared as described below and tested under specified conditions below.

### 1. Inorganic Filler-Containing Varnish

Components from each Example or each Comparative Example were added to a stirred tank according to the amounts listed in Tables 1-6 for stirring, fully dissolved at 25° C. to 80° C. and well-mixed to form a resin composition containing inorganic filler, which is designated as an inorganic filler-containing varnish.

### 2. Inorganic Filler-Free Varnish

Components except for the inorganic filler from each Example or each Comparative Example were added to a stirred tank according to the amounts listed in Tables 1-6 for stirring, fully dissolved at 25° C. to 80° C. and well-mixed to form a resin composition not containing inorganic filler, which is designated as an inorganic filler-free varnish.

### 3. Copper-Clad Cured Product

A mold (such as a fully cured laminate) was prepared, and a groove was formed on the mold. The inorganic filler-containing varnish prepared from each Example or each Comparative Example was placed into the groove, and the upper and lower surfaces were covered with a copper foil (such as a 1-ounce HVLP copper foil), followed by being subjected to lamination under vacuum at high temperature and high pressure to the C-stage, with a curing temperature of between 200° C. and 210° C., a curing time of 120 to 150 minutes and a lamination pressure of between 400 psi and 500 psi. After being cured completely, the sample was milled according to the shape of the groove by using a milling cutter with a diameter of 1.6 mm of a numerical control forming machine (model No. TQZX-II) to obtain a cured product with upper and lower surfaces covered with copper foils, abbreviated as a copper-clad cured product, which was subjected to the measurement of copper foil peeling strength.

### 4. Copper-Free Cured Product

The copper-clad cured product was etched to remove the copper foil on the upper and lower surfaces to obtain a copper-free cured product, which was subjected to the measurement of dissipation factor, glass transition temperature, percent of thermal expansion in Z-axis and water absorption ratio.

For each sample, test items and test methods are described below.

### 1. Varnish Shelf Life

The inorganic filler-free varnish was stood still at 25° C., daily observed by naked eyes to determine whether or not the varnish precipitates to form brown solid substance and subjected to the measurement of the viscosity of the varnish. The varnish was observed for 90 days, and the time to appear varnish precipitates or a viscosity variation of greater than or equal to 10% was recorded. If no precipitate was observed after 90 days, and the varnish viscosity variation was less than 10%, a designation of “>90” was given, indicating that the varnish shelf life is greater than 90 days, such as a varnish shelf life of 91 to 180 days, a varnish shelf life of 91 to 100 days or a varnish shelf life of 91 to 95 days. The presence of at least one precipitate of 0.5 to 5 mm in length, usually in brown color, was designated as “precipitation”. At the same time, the observation was stopped, and the number of days to precipitate was recorded. Precipitation of the varnish will cause variation and deterioration in properties of the cured product. If no precipitate was found in the varnish, but the varnish viscosity variation was greater than or equal to 10%, the observation would be stopped and the number of days to the date when the varnish viscosity variation was greater than or equal to 10% was recorded.

### 2. Percent of Organic Volatile Matters

The inorganic filler-containing varnish sample was placed in an aluminum tray and measured by reference to IPC-TM-650 2.4.24.6 (2012) at a temperature increase rate of 10° C./min from 50° C. to 550° C. The weight loss percentage at 150° C. was recorded (in %) to represent the percent of organic volatile matters of the resin composition.

### 3. Dissipation Factor (Df)

The copper-free cured product sample was measured by using a microwave dielectrometer (available from AET Corp.) by reference to JIS C2565 (1992) at room temperature (about 25° C.) and under 10 GHz frequency. Under a 10 GHz frequency, for a Df value of less than 0.005, a difference in Df of greater than or equal to 0.0001 represents a substantial difference in dissipation factor in different cured products (i.e., significant technical difficulty).

### 4. Glass Transition Temperature (Tg)

The copper-free cured product sample was subjected to the measurement of glass transition temperature by using thermal mechanical analysis (TMA). Each sample was heated from 35° C. to 350° C. at a heating rate of 10° C./minute and then subjected to the measurement of glass transition temperature (° C.) by reference to the method described in IPC-TM-650 2.4.24.5 (2012). In the technical field to which the present disclosure pertains, higher glass transition temperature is better. A difference in glass transition temperature of greater than or equal to 5° C. represents a substantial difference in glass transition temperature of different cured products.

### 5. Percent of Thermal Expansion in Z-Axis (Z-PTE)

The copper-free cured product sample was subjected to thermal mechanical analysis (TMA) by reference to IPC-TM-650 2.4.24.5 (2012). Each sample was heated from 50° C. to 260° C. at a heating rate of 10° C./minute and then subjected to the measurement of percent (%) of thermal expansion in Z-axis in a temperature range of 50° C. to 260° C. When the test value of percent of thermal expansion in Z-axis is less than or equal to 2%, a difference in the test values of percent of thermal expansion in Z-axis of greater than or equal to 0.1% represents a substantial difference (i.e., significant technical difficulty) in different samples. For example, the difference in the test values of Example E1 and Comparative Example C1 of the present disclosure is 1.9%-1.3%=0.6%, representing a substantial difference between E1 and C1; on the other hand, compared to Comparative Example C1, the percent of thermal expansion in Z-axis of Example E1 is improved by (0.6%/1.9%)*100%=31.57%; that is, compared to Comparative Example C1, the percent of thermal expansion in Z-axis of Example E1 is reduced by 31.57%.

### 6. Copper Foil Peeling Strength (Peeling Strength, P/S)

The copper-clad cured product was cut into a rectangular sample with a width of 24 mm and a length of greater than 60 mm, which was etched to remove surface copper foil and leave a rectangular copper foil with a width of 3.18 mm and a length of greater than 60 mm to be tested by using a tensile strength tester by reference to IPC-TM-650 2.4.8 (2012) at room temperature (about 25° C.) to measure the force (lb/in) required to separate the copper foil from the surface of the cured product.

### 7. Water Absorption Ratio

The copper-free cured product sample was placed in a 105±10° C. oven and baked for 1 hour by reference to IPC-TM-650 2.6.2.1 (2012) and then cooled at room temperature (about 25° C.) for 10 minutes and weighed to give a weight value W₁; then the sample was subjected to a pressure cooking test (PCT) by reference to IPC-TM-650 2.6.16.1 for 3 hours of moisture absorption (test temperature of 121° C. and relative humidity of 100%). The sample was taken out and then cooled and wiped to remove residual water on the surface. The sample was weighed again to give a weight value W₂, and the water absorption ratio was calculated as follows:

$$water absorption rate ( \% ) = [ ( {W}_{2} - {W}_{1} ) / {W}_{1} ] * 100 \% .$$

### 8. Percent of Cure Shrinkage

The density of the inorganic filler-containing varnish (designated as pₐ) and the density of the copper-free cured product (designated as p_{b}) were separately measured by reference to GB/T4472-2011. The total percent of volume shrinkage before and after curing was calculated as percent of cure shrinkage (Vₛ), and the formula was as follows:

$${V}_{s} = [ ( {ρ}_{b} - {ρ}_{a} ) / {ρ}_{b} ] * 100 \% .$$

The following observations can be made from Table 1 to Table 6.

If 100 parts by weight of a maleic anhydride-modified polyolefin, 5 to 40 parts by weight of a maleimide resin and 30 to 90 parts by weight of an acrylate monomer (having two or more unsaturated C═C double bonds) and/or its oligomer are used, such as Examples E1 to E24, in contrast to using 100 parts by weight of a maleic anhydride-modified polyolefin, 5 to 40 parts by weight of a maleimide resin and an amount not within 30 to 90 parts by weight of an acrylate monomer (having two or more unsaturated C═C double bonds) and/or its oligomer, such as Comparative Examples C1 to C3 (no acrylate monomer (having two or more unsaturated C═C double bonds) and/or its oligomer was present in C1, 20 parts by weight of an acrylate monomer (having two or more unsaturated C═C double bonds) and/or its oligomer was used in C2, and 100 parts by weight of an acrylate monomer (having two or more unsaturated C═C double bonds) and/or its oligomer was used in C3, each of the aforesaid amounts in all three Comparative Examples not within the range of 30 to 90 parts by weight), significant improvements at least in the following property will be achieved: varnish shelf life, wherein all samples in Examples E1 to E24 have a varnish shelf life of greater than 90 days, while the varnishes of Comparative Examples C1 to C3 precipitate after 1 day of storage or only have a varnish shelf life of 75 days.

If 100 parts by weight of a maleic anhydride-modified polyolefin, 5 to 40 parts by weight of a maleimide resin and 30 to 90 parts by weight of an acrylate monomer (having two or more unsaturated C═C double bonds) and/or its oligomer are used, such as Examples E1 to E24, in contrast to using 100 parts by weight of a maleic anhydride-modified polyolefin, 30 to 90 parts by weight of an acrylate monomer (having two or more unsaturated C═C double bonds) and/or its oligomer and an amount not within 5 to 40 parts by weight of a maleimide resin, such as Comparative Examples C4 to C5 (no maleimide resin was present in C4, and 50 parts by weight of a maleimide resin was used in C5, both amount not within the range of 5 to 40 parts by weight), significant improvements at least in the following property will be achieved: varnish shelf life, wherein all samples in Examples E1 to E24 have a varnish shelf life of greater than 90 days, while the varnishes in Comparative Examples C4 to C5 precipitate after 1 day of storage or only have a varnish shelf life of 60 days.

If 100 parts by weight of a maleic anhydride-modified polyolefin, 5 to 40 parts by weight of a maleimide resin and 30 to 90 parts by weight of an acrylate monomer (having two or more unsaturated C═C double bonds) and/or its oligomer are used, such as Examples E1 to E24, in contrast to not using any maleic anhydride-modified polyolefin but containing 5 to 40 parts by weight of a maleimide resin and 30 to 90 parts by weight of an acrylate monomer (having two or more unsaturated C═C double bonds) and/or its oligomer, such as Comparative Example C6, significant improvements at least in the following property will be achieved: varnish shelf life, wherein all samples in Examples E1 to E24 have a varnish shelf life of greater than 90 days, while Comparative Example C6 only has a varnish shelf life of 80 days.

If a maleic anhydride-modified polyolefin, a maleimide resin and an acrylate monomer (having two or more unsaturated C═C double bonds) and/or its oligomer are used, such as Examples E1 to E24, in contrast to using a polyolefin different from the maleic anhydride-modified polyolefin, a maleimide resin and an acrylate monomer (having two or more unsaturated C═C double bonds) and/or its oligomer, such as Comparative Examples C7 to C9 (polybutadiene Ricon 130 was used in C7, hydrogenated styrene-butadiene-styrene block copolymer G1726 was used in C8, and styrene-butadiene-styrene triblock copolymer SBS-A was used in C9), significant improvements at least in the following properties will be achieved: varnish shelf life, percent of organic volatile matters and copper foil peeling strength, wherein all samples in Examples E1 to E24 have a varnish shelf life of greater than 90 days, a percent of organic volatile matters of less than or equal to 0.5% and a copper foil peeling strength of greater than or equal to 4.5 lb/in, while the varnish in each of Comparative Examples C7 to C9 precipitates after 1 day of storage or only has a varnish shelf life of 35 days, the percent of organic volatile matters is greater than or equal to 0.6%, and the copper foil peeling strength is less than or equal to 3.4 lb/in.

If a maleic anhydride-modified polyolefin, a maleimide resin and an acrylate monomer (having two or more unsaturated C═C double bonds) and/or its oligomer are used, such as Examples E1 to E24, in contrast to using a maleic anhydride-modified polyolefin, a maleimide resin and an acrylate component different from the acrylate monomer (having two or more unsaturated C═C double bonds) and/or its oligomer, such as Comparative Examples C10 to C12 (acrylate SR420 containing only one unsaturated C═C double bond was used in C10, acrylate elastomer SG-P3 was used in C11, and acrylate elastomer PMS-22-1 was used in C12), significant improvements at least in the following properties will be achieved: dissipation factor, glass transition temperature, percent of thermal expansion in Z-axis, water absorption ratio and percent of cure shrinkage, wherein all samples in Examples E1 to E24 have a dissipation factor of less than or equal to 0.0038, a glass transition temperature of greater than or equal to 160° C., a percent of thermal expansion in Z-axis of less than or equal to 1.6%, a water absorption ratio of less than or equal to 0.60% and a percent of cure shrinkage of less than or equal to 6.0%, and Comparative Examples C10 to C12 have a dissipation factor of greater than or equal to 0.0041, a glass transition temperature of less than or equal to 150° C., a percent of thermal expansion in Z-axis of greater than or equal to 2.1%, a water absorption ratio of greater than or equal to 0.65% and a percent of cure shrinkage of greater than or equal to 7.5%.

From the observation of Examples E1 to E24, it can be found that using a resin composition or an article made therefrom according to the present disclosure can achieve improvements in one, more or all properties including varnish shelf life, percent of organic volatile matters, dissipation factor, glass transition temperature, percent of thermal expansion in Z-axis, copper foil peeling strength, water absorption ratio and percent of cure shrinkage.

In addition, by further study of the test results of Examples E1 to E24, the following observations can be made.

In Examples E1 to E24, by comparing E20 to E24 with E1 to E19, it can be found that when an organic silicone oil is added to the resin composition, at least one performance is significantly improved, especially a higher copper foil peeling strength, and when the organic silicone oil is preferably an unsaturated C═C double bond-containing organic silicone oil, the copper foil peeling strength can be further improved.

The above detailed description is merely illustrative in nature and is not intended to limit the embodiments of the subject matter or the applications and uses of such embodiments. As used herein, the term “exemplary” or similar expression means “serving as an example, instance, or illustration.” Any implementation described herein as exemplary is not necessarily to be construed as preferred or advantageous over other implementations, unless otherwise specified.

Moreover, while at least one exemplary example or comparative example has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments and equivalents thereof. Also, the scope defined by the claims includes known equivalents and foreseeable equivalents at the time of filing this patent application.

What is claimed is:

1. A resin composition, comprising:
100 parts by weight of a maleic anhydride-modified polyolefin;
5 to 40 parts by weight of a maleimide resin; and
30 to 90 parts by weight of an acrylate monomer, its oligomer or a combination thereof, the acrylate monomer having two or more unsaturated C═C double bonds.

2. The resin composition of claim 1, wherein the maleic anhydride-modified polyolefin comprises maleic anhydride-adducted polybutadiene, maleic anhydride-adducted polyisoprene, maleic anhydride-adducted styrene-butadiene copolymer, maleic anhydride-adducted styrene-isoprene copolymer, maleic anhydride-styrene copolymer or a combination thereof.

3. The resin composition of claim 1, wherein the maleimide resin comprises 4,4′-diphenylmethane bismaleimide, polyphenylmethane maleimide, bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-dimethylphenyl maleimide, N-2,6-dimethylphenyl maleimide, N-phenylmaleimide, vinyl benzyl maleimide, maleimide containing indane structure, maleimide containing isopropyl and m-arylene structures, maleimide containing biphenylalkylene structure, maleimide containing aliphatic structure with 10 to 50 carbon atoms, or a combination thereof.

4. The resin composition of claim 1, wherein the maleimide resin has a maleimide group and an aromatic group bonded with the maleimide group.

5. The resin composition of claim 1, wherein the acrylate monomer comprises tricyclodecane dimethanol di(meth)acrylate, dioxane glycol di(meth)acrylate, dipropylene glycol di(meth)acrylate, tris(2-hydroxyethyl)isocyanurate tri(meth)acrylate, pentaerythritol tri(meth)acrylate, pentaerythritol tetra(meth)acrylate, di-trimethylolpropane tetra(meth)acrylate, dipentaerythritol penta(meth)acrylate, dipentaerythritol hexa(meth)acrylate or a combination thereof.

6. The resin composition of claim 1, wherein the acrylate monomer has two acrylate groups or three acrylate groups.

7. The resin composition of claim 1, wherein the acrylate monomer or its oligomer has a glass transition temperature of greater than or equal to 90° C. after curing.

8. The resin composition of claim 1, wherein the acrylate monomer or its oligomer has a glass transition temperature of greater than or equal to 150° C. after curing.

9. The resin composition of claim 1, characterized by not comprising an organic solvent.

10. The resin composition of claim 1, further comprising 1 to 10 parts by weight of an organic silicone oil.

11. The resin composition of claim 10, wherein the organic silicone oil contains an unsaturated C═C double bond.

12. The resin composition of claim 1, further comprising a polyolefin different from the maleic anhydride-modified polyolefin, an unsaturated C═C double bond-containing polyphenylene ether resin, a benzoxazine resin, an epoxy resin, an active ester, a phenol resin, an amine curing agent, a polyamide, a polyimide, a cyanate ester resin or a combination thereof.

13. The resin composition of claim 1, further comprising an inorganic filler, a flame retardant, a curing accelerator, a polymerization inhibitor, a coloring agent, a surfactant, a toughening agent or a combination thereof.

14. The resin composition of claim 1, having a varnish shelf life of greater than 90 days.

15. The resin composition of claim 1, having a percent of organic volatile matters as measured by reference to IPC-TM-650 2.4.24.6 of less than or equal to 0.5%.

16. An article made from the resin composition of claim 1, wherein the article comprises a prepreg, a resin film, a laminate, or a printed circuit board.

17. An article made from the resin composition of claim 1, wherein the article comprises a cured product obtained by curing the resin composition.

18. The article of claim 17, which has a dissipation factor at 10 GHz as measured by reference to JIS C2565 of less than or equal to 0.0038.

19. The article of claim 17, which has a glass transition temperature as measured by reference to IPC-TM-650 2.4.24.5 of greater than or equal to 160° C.

20. The article of claim 17, which has a percent of thermal expansion in Z-axis as measured by reference to IPC-TM-650 2.4.24.5 of less than or equal to 1.6%.

21. The article of claim 17, which has a copper foil peeling strength as measured by reference to IPC-TM-650 2.4.8 of greater than or equal to 4.5 lb/in.

22. The article of claim 17, which has a water absorption ratio as measured by reference to IPC-TM-650 2.6.2.1 and IPC-TM-650 2.6.16.1 of less than or equal to 0.60%.

23. The article of claim 17, which has a percent of cure shrinkage as measured and calculated by reference to GB/T4472-2011 of less than or equal to 6.0%.

24. A use of the resin composition of claim 1 in a printed circuit board hole-plugging process or a printed circuit board circuit filling process.

25. The use of claim 24, wherein, in the printed circuit board hole-plugging process, at least one electroplated hole of a printed circuit board is filled with a cured product of the resin composition, and, in the printed circuit board circuit filling process, at least one circuit open area of a printed circuit board is covered with a cured product of the resin composition.
